(19) United States
(12) Patent Application Publication
(10) Pub. No.: US 2024/0188310 A1
(43) Pub. Date: Jun. 6, 2024

(54) SEMICONDUCTOR MEMORY DEVICE

(71) Applicant: Kioxia Corporation, Tokyo (JP)

(72) Inventor: Hiroto SAITO, Yokkaichi Mie (JP)

(21) Appl. No.: 18/453,919

(22) Filed: Aug. 22, 2023

(30) Foreign Application Priority Data
Dec. 2, 2022 (JP) 2022-193540

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/14511

(57) ABSTRACT

According to one embodiment, a semiconductor memory device includes a first chip and a second chip contacting the first chip. The second chip includes a memory cell array. First bonding pads are on the first chip. Second bonding pads are on the second chip and contact the first bonding pads. A first electrode pad is in a first plane parallel with the first bonding pads. A second electrode pad is in a second plane with the second bonding pads. A first insulator layer is interposed between the first electrode pad and the second electrode pad.

### CROSS-REFERENCE TO RELATED APPLICATION (S)

This application is based upon and claims the benefit of priority from Japanese Patent Application No. 2022-193540, filed Dec. 2, 2022, the entire contents of which are incorporated herein by reference.

### FIELD

Embodiments described herein relate generally to a semiconductor memory device.

### BACKGROUND

A NAND flash memory is a known type of semiconductor memory device capable of storing data in a nonvolatile manner. In a NAND flash memory, three-dimensional memory structure is employed for high integration and large capacity.

### BRIEF DESCRIPTION OF THE DRAWINGS

FIG. 1 is a block diagram of a memory system including a semiconductor memory device according to an embodiment.

FIG. 2 is a circuit diagram of a memory cell array provided in a semiconductor memory device according to an embodiment.

FIG. 3 is a cross-sectional view of a memory cell array provided in a semiconductor memory device according to an embodiment.

FIG. 4 is a cross-sectional view of a semiconductor memory device according to an embodiment.

FIG. 5 is a cross-sectional view of a semiconductor memory device according to an embodiment.

FIG. 6 is a cross-sectional view of bonding pads and a capacitive element provided in a semiconductor memory device according to an embodiment.

FIG. 7 is a cross-sectional view illustrating aspects of a method for manufacturing a semiconductor memory device according to an embodiment.

FIG. 8 is a top view illustrating an example of a method for manufacturing a semiconductor memory device according to an embodiment.

FIGS. 9-15 are cross-sectional views illustrating aspects of a method for manufacturing a semiconductor memory device according to an embodiment.

FIG. 16 is a cross-sectional view of a semiconductor memory device according to a Modified Example 1.

FIG. 17 is a cross-sectional view of a semiconductor memory device according to a Modified Example 1.

FIG. 18 is a cross-sectional view of a semiconductor memory device according to a Modified Example 2.

FIG. 19 is a cross-sectional view of a semiconductor memory device according to a Modified Example 2.

FIG. 20 is a top view illustrating aspects of a method for manufacturing a semiconductor memory device according to a Modified Example 2.

FIGS. 21-25 are cross-sectional views illustrating aspects of a method for manufacturing a semiconductor memory device according to a Modified Example 2.

FIG. 26 is a cross-sectional view of a semiconductor memory device according to a Modified Example 3.

FIG. 27 is a cross-sectional view of a semiconductor memory device according to a Modified Example 4.

FIG. 28 is a cross-sectional view of a semiconductor memory device according to a Modified Example 4.

### DETAILED DESCRIPTION

In general, according to one embodiment, a semiconductor memory device includes a first chip including a substrate and a second chip in contact with the first chip. The second chip includes a memory cell array with a plurality of first wiring layers separated from each other in a first direction perpendicular to an upper surface of the substrate and a plurality of memory pillars penetrating the plurality of first wiring layers in the first direction. A plurality of first bonding pads is on the first chip. A plurality of second bonding pads is on the second chip. The second bonding pads are in contact with the plurality of first bonding pads. A first electrode pad is in a first plane parallel to the upper surface of the substrate with the plurality first bonding pads. A second electrode pad faces the first electrode pad in the first direction and is in a second plane parallel to the upper surface of the substrate with the plurality of second bonding pads. The second electrode pad is separated from the first electrode pad in the first direction. A first insulator layer is interposed in the first direction between the first electrode pad and the second electrode pad.

Certain example embodiments will be described with reference to the drawings. It is noted that the dimensions and ratios depicted in the drawings are not necessarily the same as those in reality. In addition, in the following description, elements having approximately the same functions and configurations are denoted by the same reference symbols. In addition, when elements of the same type having similar configurations are to be distinguished, different letters or numerals may be added as suffixes or the like to the otherwise same reference symbols.

### 1. EMBODIMENT

A semiconductor memory device according to an embodiment will be described below.

### 1.1 Configuration

A configuration of the semiconductor memory device according to the embodiment will be described.

### 1.1.1 Memory System

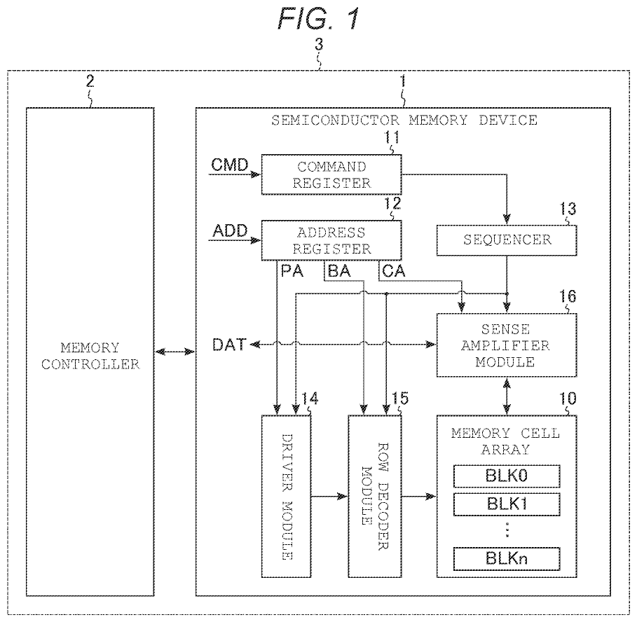

First, a configuration example of a memory system will be described with reference to FIG. 1. FIG. 1 is a block diagram illustrating an example of a configuration of the memory system including the semiconductor memory device according to the embodiment.

A memory system 3 is, for example, a solid-state drive (SSD) or a SD™ card. The memory system 3 is connected, for example, to an external host device. The memory system 3 stores data from the host device. In addition, the memory system 3 reads data to the host device.

The memory system 3 includes a semiconductor memory device 1 and a memory controller 2.

The semiconductor memory device 1 is, for example, a NAND flash memory. The semiconductor memory device 1 stores data in a nonvolatile manner. A case where the semiconductor memory device 1 is the NAND flash memory will be described below as an example.

The memory controller 2 is, for example, an integrated circuit such as system-on-a-chip (SoC). The memory controller 2 writes data to the semiconductor memory device 1 based on a request from the host device. In addition, the memory controller 2 reads data from the semiconductor memory device 1 based on the request from the host device. The memory controller 2 transmits data read from the semiconductor memory device 1 to the host device.

Communication between the semiconductor memory device 1 and the memory controller 2 conforms to, for example, a single data rate (SDR) interface, a toggle double data rate (DDR) interface, or an open NAND flash interface (ONFI).

### 1.1.2 Semiconductor Memory Device

An internal configuration of the semiconductor memory device 1 will be described with reference to FIG. 1. The semiconductor memory device 1 includes a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). Each block BLK is a set (group) of memory cells capable of storing data in a nonvolatile manner. The block BLK is used, for example, as a data erase unit. The memory cell array 10 has a plurality of bit lines and a plurality of word lines. One memory cell is associated with one bit line and one word line.

The command register 11 stores a command CMD received by the semiconductor memory device 1 from the memory controller 2. The command CMD can be an instruction to cause the sequencer 13 to perform a read operation, a write operation, an erase operation, and the like.

The address register 12 stores address information ADD received by the semiconductor memory device 1 from the memory controller 2. The address information ADD can be or include page addresses PA, block addresses BA, and column addresses CA. The page addresses PA, the block addresses BA, and the column addresses CA are used to select the word lines, the blocks BLK, and the bit lines.

The sequencer 13 controls the overall operations of the semiconductor memory device 1. The sequencer 13 executes a read operation, a write operation, or an erase operation based on the command CMD stored in the command register 11.

The driver module 14 generates voltages used in the read, write, and erase operations, and the like. The driver module 14 applies the generated voltage to a signal line corresponding to the selected word line based on the page address PA stored in the address register 12.

The row decoder module 15 selects one block BLK in the corresponding memory cell array 10 based on the block address BA stored in the address register 12. Then, the row decoder module 15 transfers the voltage applied to the signal line corresponding to the selected word line to the selected word line in the selected block BLK.

The sense amplifier module 16 transfers data DAT between the memory controller 2 and the memory cell array 10. The data DAT can be write data or read data. More specifically, the sense amplifier module 16 transfers the write data DAT received from the memory controller 2 to the memory cell array 10 in a write operation. The sense amplifier module 16 also performs a determination (identification) of the data stored in the memory cells based on the voltages on the bit lines in a read operation. The sense amplifier module 16 transfers the determination result as the read data DAT to the memory controller 2.

### 1.1.3 Circuit Configuration of Memory Cell Array

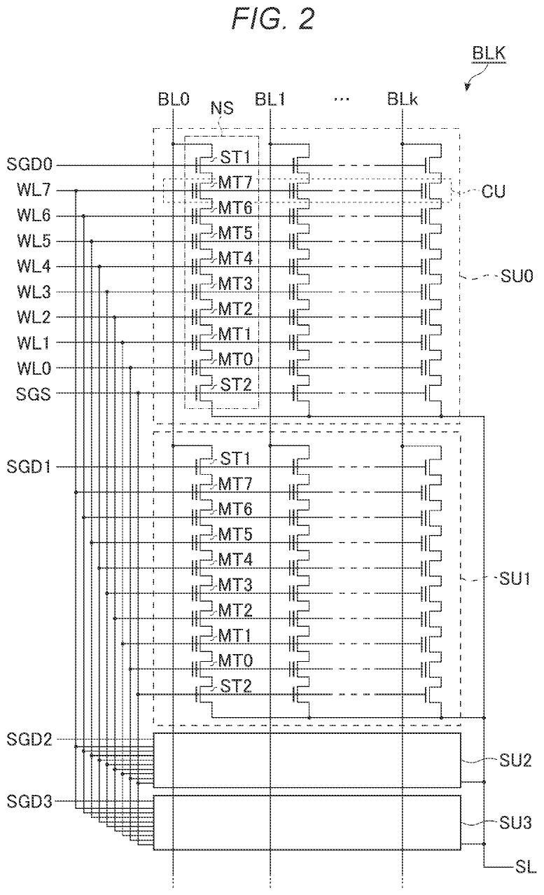

An example of the circuit configuration of the memory cell array 10 will be described with reference to FIG. 2. FIG. 2 is a circuit diagram of the memory cell array provided in the semiconductor memory device 1 according to the embodiment. FIG. 2 illustrates one block BLK among the plurality of blocks BLK provided in the memory cell array 10. In the example illustrated in FIG. 2, a block BLK includes four string units SU0, SU1, SU2, and SU3.

Each string unit SU includes a plurality of NAND strings NS respectively associated with the bit lines BL0 to BLk (k is an integer of 1 or more). In this example, NAND string NS includes memory cell transistors MT0 to MT7 and select transistors ST1 and ST2. Each of memory cell transistors MT0 to MT7 includes a control gate and a charge storage film. Each of memory cell transistors MT0 to MT7 stores data in a non-volatile manner. The select transistors ST1 and ST2 are used to select the string unit SU during various operations. It is noted that, in the following description, when the bit lines BL0 to BLk are not being distinguished from one another, each may be simply referred to as a bit line BL. In addition, when the memory cell transistors MT0 to MT7 are not being distinguished from one another, each may be simply referred to as a memory cell transistor MT.

In each NAND string NS, the memory cell transistors MT0 to MT7 are connected in series. A first end of the select transistor ST1 is connected to the associated bit line BL of the select transistor ST1. A second end of the select transistor ST1 is connected to one end of the memory cell transistors MT0 to MT7 connected in series. A first end of the select transistor ST2 is connected to the other end of the memory cell transistors MT0 to MT7 connected in series. A second end of the select transistor ST2 is connected to a source line SL.

In the same block BLK, the control gates of the all memory cell transistors MT0 to MT7 are respectively connected to word lines WL0 to WL7. The gates of the select transistors ST1 in the string units SU0 to SU3 are connected to select gate lines SGD0 to SGD3, respectively. On the other hand, the gates of the plurality of select transistors ST2 are connected in common to a select gate line SGS. However, the present disclosure is not limited to this, and the gates of the select transistors ST2 may be connected to a plurality of select gate lines SGS that are different for each string unit SU. It is noted that, in the following description, when the word lines WL0 to WL7 are not being distinguished from each other, each may be simply referred to as a word line WL. In addition, when the select gate lines SGD0 to SGD3 are not being distinguished from each other, each may be simply referred to as a select gate line SGD.

Different column addresses are allocated to each of the bit lines BL0 to BLk. A bit line BL is shared by all the NAND strings NS allocated with the same column address among the plurality of blocks BLK. The word lines WL0 to WL7 are provided separately for each block BLK. The source line SL can be shared among the plurality of blocks BLK.

A set of memory cell transistors MT connected to a same word line WL in one string unit SU is called a cell unit CU. The storage capacity of a cell unit CU when each memory cell transistor MT is capable of storing 1-bit data is defined as “1 page data” or “one page worth of data” or “one page unit of data”. A cell unit CU may have a storage capacity of two or more page data units according to the number of bits of data storable in each memory cell transistor MT.

It is noted that the circuit configuration of the memory cell array 10 is not limited to the configuration described above. For example, the number of string units SU provided in each block BLK may be any number. The number of the memory cell transistors MT and the number of select transistors ST1 and ST2 provided in each NAND string NS may be any number.

### 1.1.4 Structure of Memory Cell Array

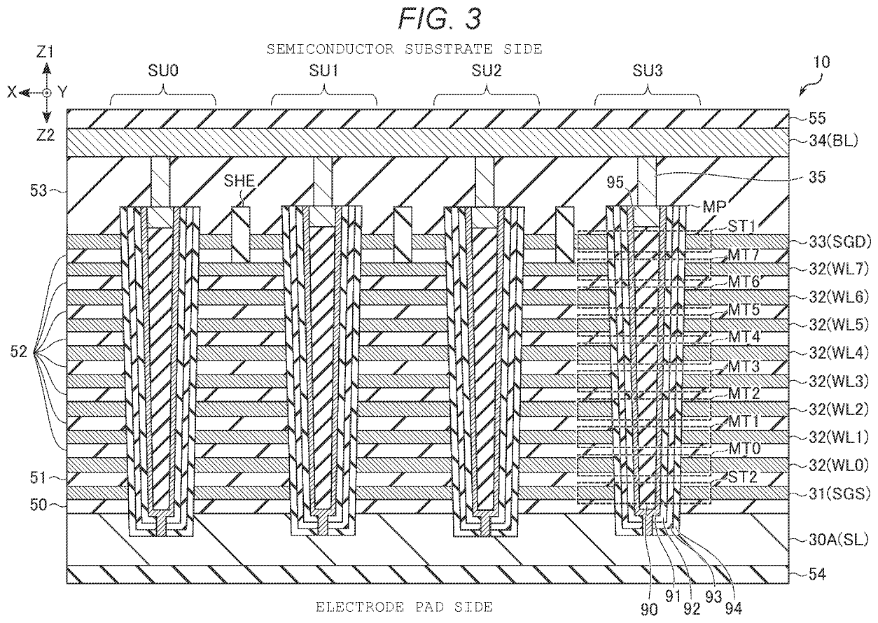

Next, the structure of the memory cell array 10 will be described with reference to FIG. 3. FIG. 3 is a cross-sectional view illustrating an example of the cross-sectional structure in an XZ plane.

In the drawings referred to below, the X direction corresponds to the extending direction of the bit lines BL, and the Y direction corresponds to the extending direction of the word lines WL. A Z1 direction corresponds to the direction from the electrode pads toward the semiconductor substrate of the semiconductor memory device 1, and a 22 direction corresponds to the direction from the semiconductor substrate toward the electrode pads of the semiconductor memory device 1. The Z1 direction or the Z2 direction can both be referred to as a Z direction. It is noted that, in the following description, the surface or end of a component on the electrode pad side are also called a first surface or a first end, respectively. In addition, the surface or end of a component on the semiconductor substrate side are also called a second surface or a second end, respectively.

The memory cell array 10 includes conductor layers 30A, 31, 33, 34, and 35, a plurality of conductor layers 32, insulator layers 50, 51, and 53, a plurality of insulator layers 52, and a plurality of memory pillars MP. FIG. 3 illustrates four memory pillars MP among the plurality of memory pillars MP. In addition, FIG. 3 illustrates a case where the eight conductor layers 32 and the eight insulator layers 52 are layered (stacked) with each other. The memory cell array 10 is provided in the Z direction between the electrode pads (electrode pad side) and the semiconductor substrate (semiconductor substrate side) of the semiconductor memory device 1.

The conductor layer 30A is formed, for example, in a plate shape spreading along the XY plane. The conductor layer 30A is used as the source line SL. The conductor layer 30A is a conductive material. The conductive material is, for example, a metal material or an N-type doped semiconductor material.

The insulator layer 50 is stacked on the second surface of the conductor layer 30A. The conductor layer 31 is stacked on the second surface of the insulator layer 50. The conductor layer 31 is formed, for example, in a plate shape spreading along the XY plane. The conductor layer 31 is used as the select gate line SGS. The conductor layer 31 comprises, for example, tungsten.

The insulator layer 51 is stacked on the second surface of the conductor layer 31. On the second surface of the insulator layer 51, the eight conductor layers 32 and the eight insulator layers 52 are stacked toward the Z1 direction in alternation. The conductor layer 32 is formed, for example, in a plate shape spreading along the XY plane. The eight conductor layers 32 are used as the word lines WL0 to WL7 in order from the conductor layer 31 side toward the Z1 direction. The conductor layer 32 comprises, for example, tungsten.

The conductor layer 33 is stacked on the second surface of the insulator layer 52 closest to the semiconductor substrate among the eight insulator layers 52. The conductor layer 33 is formed, for example, in a plate shape spreading along the XY plane. The conductor layer 33 is used as the select gate line SGD. The conductor layer 33 comprises, for example, tungsten. The conductor layer 33 can be electrically separated for each string unit SU by members SHE (isolation features).

The insulator layer 53 is stacked on the second surface of the conductor layer 33. The conductor layer 34 is stacked on the second surface of the insulator layer 53. Each conductor layer 34 is provided extending along the X direction. The conductor layer 34 functions as a bit line BL.

The stacked structure including the conductor layers 30A, 31, 33, and 34, the eight conductor layers 32, the insulator layers 50, 51, and 53, and the eight insulator layers 52 is surrounded by insulator layers 54 and 55. FIG. 3 illustrates the insulator layer 54 in contact with the first surface of the conductor layer 30A and the insulator layer 55 in contact with the second surface of the conductor layer 34.

The plurality of memory pillars MP are provided extending along the Z direction on the electrode pad side of the conductor layer 34. The plurality of memory pillars MP pass through the conductor layers 31 and 33 and the eight conductor layers 32.

Each of the memory pillars MP includes, for example, a core member 90, a semiconductor film 91, a tunnel insulating film 92, a charge storage film 93, a block insulating film 94, and a semiconductor portion 95.

The core member 90 is provided extending along the Z direction. In the Z direction, the first end of the core member 90 is located closer to the semiconductor substrate than the conductor layer 30A. In the Z direction, the second end of the core member 90 is located closer to the semiconductor substrate than the conductor layer 33. The core member 90 comprises, for example, silicon oxide.

The semiconductor film 91 covers the side surface (outer peripheral surface) of the core member 90. In the Z direction, the first end of the semiconductor film 91 covers the first end of the core member 90. In the Z direction, the first end of the semiconductor film 91 is in contact with the conductor layer 30A. In the Z direction, the second end of the semiconductor film 91 is located closer to the semiconductor substrate than the second end of the core member 90. The semiconductor film 91 comprises, for example, polysilicon.

The tunnel insulating film 92 covers the side surface of the semiconductor film 91. The second end of the tunnel insulating film 92 is located at the same height as the second end of the semiconductor film 91 in the Z direction. The tunnel insulating film 92 comprises, for example, silicon oxide.

The charge storage film 93 covers the side surface of the tunnel insulating film 92. In the Z direction, the second end of the charge storage film 93 is located at the same height as the second end of the semiconductor film 91 and the second end of the tunnel insulating film 92. The charge storage film 93 includes an insulator capable of storing charges. The insulator is, for example, silicon nitride.

The block insulating film 94 covers the side surface of the charge storage film 93. In the Z direction, the second end of the block insulating film 94 is located at the same height as the second end of the semiconductor film 91, the second end of the tunnel insulating film 92, and the second end of the charge storage film 93. The block insulating film 94 comprises, for example, silicon oxide.

The semiconductor portion 95 covers the second surface of the core member 90 in the Z direction. The side surface of the semiconductor portion 95 is covered with the second end of the semiconductor film 91.

The conductor layer 35 is in contact with the semiconductor portion 95 and the conductor layer 34 respectively between the semiconductor portion 95 and the conductor layer 34 along the Z direction.

A portion where a memory pillar MP and the conductor layer 31 intersect functions as a select transistor ST2. A portion where a memory pillar MP intersect with each of the conductor layers 32 functions as a memory cell transistor MT. A portion where a memory pillar MP and the conductor layer 33 intersect functions as a select transistor ST1. The semiconductor film 91 functions as the channels of the memory cell transistors MT0 to MT7 and the select transistors ST1 and ST2. The charge storage film 93 functions as a charge storage layer of the memory cell transistor MT.

### 1.1.5 Structure of Semiconductor Memory Device

An example of the structure of the semiconductor memory device 1 according to the embodiment will be described below.

### 1.1.5.1 Cross-Sectional Structure of Semiconductor Memory Device

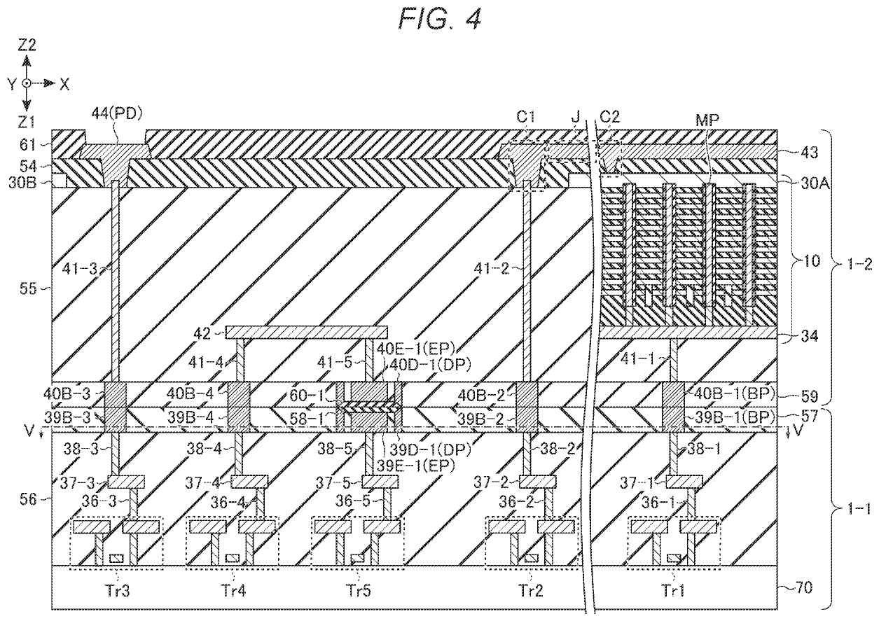

FIG. 4 is a cross-sectional view illustrating an example of the cross-sectional structure of the semiconductor memory device 1 according to the embodiment in an XZ plane. FIG. 4 illustrates a cross-sectional structure of a portion of the semiconductor memory device 1.

The semiconductor memory device 1 has a structure in which a circuit chip 1-1 and a memory chip 1-2 are bonded together.

First, the cross-sectional structure of the circuit chip 1-1 will be described.

The circuit chip 1-1 includes a semiconductor substrate 70, transistors Tr1, Tr2, Tr3, Tr4, and Tr5, a plurality of conductor layers 36, 37, 38, 39B, 39D, and 39E, insulator layers 56 and 57, and a plurality of insulator layers 58. The transistors Tr1, Tr2, Tr3, Tr4, and Tr5 are elements in peripheral circuits forming the command register 11, the address register 12, the sequencer 13, the driver module 14, the row decoder module 15, the sense amplifier module 16, and the like. The transistors Tr1, Tr2, and Tr3 are electrically connected to the bit lines BL, the source lines SL, and the electrode pads PD, respectively. The transistors Tr4 and Tr5 are electrically connected to capacitive elements.

The insulator layer 56 is provided on a first surface of the semiconductor substrate 70. The insulator layer 56 comprises, for example, silicon oxide. In the insulator layer 56, the transistors Tr1, Tr2, Tr3, Tr4, and Tr5 and the plurality of conductor layers 36, 37, and 38 are provided.

The plurality of conductor layers 36 include conductor layers 36-1, 36-2, 36-3, 36-4, and 36-5. The conductor layers 36-1, 36-2, 36-3, 36-4, and 36-5 are connected to the transistors Tr1, Tr2, Tr3, Tr4, and Tr5, respectively. Each of the conductor layers 36 functions as a columnar contact.

The plurality of conductor layers 37 include conductor layers 37-1, 37-2, 37-3, 37-4, and 37-5. The conductor layers 37-1, 37-2, 37-3, 37-4, and 37-5 are connected to the first surfaces of the conductor layers 36-1, 36-2, 36-3, 36-4, and 36-5, respectively.

The plurality of conductor layers 38 include conductor layers 38-1, 38-2, 38-3, 38-4, and 38-5. The conductor layers 38-1, 38-2, 38-3, 38-4, and 38-5 are connected to the first surfaces of the conductor layers 37-1, 37-2, 37-3, 37-4, and 37-5, respectively. The first surfaces of the plurality of conductor layers 38 are flush (level) with the first surface of the insulator layer 56.

The insulator layer 57 is provided on the first surfaces of the insulator layer 56 and the plurality of conductor layers 38. The insulator layer 57 comprises, for example, silicon oxide.

The plurality of conductor layers 39B, 39D, and 39E are provided in the same layer as the insulator layer 57. Each of the conductor layers 39B, 39D, and 39E comprises, for example, copper.

The plurality of conductor layers 39B include conductor layers 39B-1, 39B-2, 39B-3, and 39B-4. The conductor layers 39B-1, 39B-2, 39B-3, and 39B-4 are connected to first surfaces of the conductor layers 38-1, 38-2, 38-3, and 38-4, respectively. Each of conductor layers 39B is provided so that the first surface of the conductor layer 39B is flush with the first surface of the circuit chip 1-1. The plurality of conductor layers 39B function as a plurality of bonding pads BP for electrically connecting the circuit chip 1-1 and the memory chip 1-2.

The plurality of conductor layers 39E include a conductor layer 39E-1. The conductor layer 39E-1 is connected to the first surface of the conductor layer 38-5. The first surfaces of the plurality of conductor layers 39E are located closer to the semiconductor substrate 70 than the first surfaces of the plurality of conductor layers 39B. The second surfaces of the plurality of conductor layers 39E are located at approximately the same height as the second surfaces of the plurality of conductor layers 39B.

It is noted that, although only the conductor layer 39E-1 among the plurality of conductor layers 39E is illustrated in the cross section illustrated in FIG. 4, the embodiment is not limited thereto. The semiconductor memory device 1 may include the two or more conductor layers 39E in the XZ plane.

The plurality of conductor layers 39D are provided corresponding to the plurality of conductor layers 39E. The plurality of conductor layers 39D include conductor layer 39D-1 corresponding to the conductor layer 39E-1. In the XZ plane, each of the conductor layers 39D includes a portion on one side of the conductor layer 39E in the X direction and another portion on the other side of the conductor layer 39E in the X direction. Each conductor layer 39D is separated from the corresponding conductor layer 39E which the conductor layer 39D surrounds. For example, in the XZ plane, a first portion of the insulator layer 57 is between the conductor layer 39D and the conductor layer 39E.

The first surfaces of the portions of conductor layer 39D have an end portion located closer to the semiconductor substrate 70 on the side nearest to the conductor layer 39E than an end portion facing outwardly from the conductor layer 39E. The first surface of each conductor layer 39E forms a dish-shaped recessed structure with the surrounding conductor layer 39D and the first surface of the interposed first portion of the insulator layer 571. The second surfaces of the conductor layers 39D are located at approximately the same height as the second surfaces of the plurality of conductor layers 39B and the second surfaces of the plurality of conductor layers 39E.

It is noted that, although only the conductor layer 39D-1 is illustrated in the cross section illustrated in FIG. 4, the embodiment is not limited thereto. The semiconductor memory device 1 may include the two or more conductor layers 39D in the XZ plane to match the number of the conductor layers 39E or the like.

In addition, although not specifically illustrated in FIG. 4, the cross-sectional structure of conductor layers 39E and the conductor layers 39D in a YZ plane is similar to the cross-sectional structure in the XZ plane.

More specifically, that is, in the YZ plane, the first surface of each of the conductor layers 39E forms a dish-shaped recessed structure with the corresponding (surrounding) conductor layer 39D and interposed first portion of the insulator layer 57 similarly to the depicted structure in the XZ plane.

The plurality of insulator layers 58 are provided corresponding to each of the plurality of conductor layers 39E. In the cross section illustrated in FIG. 4, the plurality of insulator layers 58 includes insulator layer 58-1 corresponding to conductor layer 39E-1. The insulator layers 58 cover (fill) the recessed dish-shaped structure on the side of the semiconductor substrate 70. The insulator layer 58-1 is provided so as to fill the dish-shaped structure formed in the XZ plane and the YZ plane by the conductor layer 39D-1, the conductor layer 39E-1, and the interposed first portion of the insulator layer 57 separating the conductor layers 39D-1 and 39E-1. Each of the insulator layers 58 is provided so that the first surface of the insulator layer 58 and the first surface of the circuit chip 1-1 are substantially flush (level) with each other. The insulator layers 58 are an insulating material. The insulating material may be, for example, silicon oxide, silicon nitride, or nitrogen-doped silicon carbide (SiCN). When the insulating material is silicon nitride or nitrogen-doped silicon carbide, diffusion of copper from the plurality of conductor layers 39D and 39E can be prevented or reduced.

It is noted that, although only the insulator layer 58-1 corresponding to the conductor layer 39E-1 among the plurality of insulator layers 58 is illustrated in the cross section illustrated in FIG. 4, the present disclosure is not limited thereto. The semiconductor memory device 1 may include the two or more insulator layers 58 in an XZ plane according to the corresponding number of the conductor layers 39E.

With the above configuration, each of the conductor layers 39E is separated from the second surface of the memory chip 1-2 by an insulator layer 58 corresponding to the conductor layer 39E.

Next, a cross-sectional structure of the memory chip 1-2 will be described.

The memory chip 1-2 includes conductor layers 30B, 42, 43, and 44, a plurality of conductor layers 40B, 40D, 40E, and 41, insulator layers 54, 55, 59, and 61, and a plurality of insulator layers 60 and the memory cell array 10.

In the memory chip 1-2, the insulator layer 59 is provided on the first surface of the circuit chip 1-1. The insulator layer 59 comprises, for example, silicon oxide.

The plurality of conductor layers 40B, 40D, and 40E are provided in the same layer as the insulator layer 59. Each of the conductor layers 40B, 40D, and 40E comprises, for example, copper.

The plurality of conductor layers 40B are provided corresponding to the plurality of conductor layers 39B. The plurality of conductor layers 40B includes conductor layers 40B-1, 40B-2, 40B-3, and 40B-4. The conductor layers 40B-1, 40B-2, 40B-3, and 40B-4 are connected to the first surfaces of the conductor layers 39B-1, 39B-2, 39B-3, and 39B-4, respectively. The plurality of conductor layers 40B function as the plurality of bonding pads BP for electrically connecting the circuit chip 1-1 and the memory chip 1-2. With these configurations, the circuit chip 1-1 and the memory chip 1-2 are electrically connected by the plurality of conductor layers 39B and 40B.

The plurality of conductor layers 40E are provided corresponding to the plurality of conductor layers 39E. Each of the conductor layers 40E and the corresponding conductor layer 39E to the conductor layer 40E are aligned in the Z direction. The first surfaces of the plurality of conductor layers 40E are located at approximately the same height as the first surfaces of the plurality of conductor layers 40B. The second surfaces of the plurality of conductor layers 40E are located closer to the electrode pad PD than the second surfaces of the plurality of conductor layers 40B.

It is noted that, although only the conductor layer 40E-1 corresponding to the conductor layer 39E-1 among the plurality of conductor layers 40E is illustrated in the cross section illustrated in FIG. 4, the embodiment is not limited thereto. The semiconductor memory device 1 may include the two or more conductor layers 40E in the XZ plane, according to the number of the conductor layers 39E.

The plurality of conductor layers 40D are provided corresponding to the plurality of conductor layers 40E. The plurality of conductor layers 40D include a conductor layer 40D-1 corresponding to the conductor layer 40E-1. In the XZ plane, each of the conductor layers 40D includes a portion on one side of the corresponding conductor layer 40E and another portion on the other side of conductor layer 40E in the X direction. Each of the conductor layers 40D is separated from the corresponding conductor layer 40E which the conductor layer 40D surrounds. For example, in the XZ plane, a portion of the insulator layer 59 is between the conductor layer 40D and the corresponding conductor layer 40E.

The second surfaces of conductor layers 40D have an end portion located closer to the electrode pad PD on the side nearest to the conductor layer 40E than an end portion facing outwardly from the conductor layer 40E. The second surface of each of conductor layer 40E forms a dish-shaped recessed structure with the surrounding conductor layer 40D and the second surface of the interposed portion of the insulator layer 59. The first surfaces of the conductor layers 40D are located at approximately the same height as the first surfaces of the plurality of conductor layers 40B and the first surfaces of the plurality of conductor layers 40E.

It is noted that, although only the conductor layer 40D-1 is illustrated in the cross section illustrated in FIG. 4, the embodiment is not limited thereto. The semiconductor memory device 1 may include the two or more conductor layers 40D in the XZ plane to match the number of the conductor layers 39E and 40E or the like.

In addition, although not specifically illustrated in FIG. 4, the cross-sectional structure of conductor layers 40D and the conductor layers 40E in a YZ plane is similar to the cross-sectional structure in the XZ plane.

More specifically, that is, in the YZ plane, the second surface of each of the conductor layers 40E forms a dish-shaped recessed structure with the corresponding (surrounding) the conductor layer 40D and the interposed portion of the insulator layer 59, similarly to the depicted structure in the XZ plane.

The plurality of insulator layers 60 are provided corresponding to the plurality of conductor layers 39E and 40E. In the cross section illustrated in FIG. 4, the plurality of insulator layers 60 includes an insulator layer 60-1 corresponding to the conductor layers 39E-1 and 40E-1. The insulator layers 60 fill the recessed dish-shaped structure on the electrode pad PD side described above. For example, the insulator layer 60-1 is provided so as to fill a dish-shaped structure formed in XZ plane and the YZ plane by the conductor layer 40D-1, the conductor layer 40E-1, and the interposed portion of the insulator layer 59 separating the conductor layers 40D-1 and 40E-1. Each of the insulator layers 60 is provided so that the second surface of the insulator layer 60 and the second surface of the memory chip 1-2 are substantially flush (level) with each other. The plurality of insulator layers 60 are an insulating material. The insulating material may be, for example, silicon oxide, silicon nitride, or nitrogen-doped silicon carbide. When the insulating material is silicon nitride or nitrogen-doped silicon carbide, diffusion of copper from the plurality of conductor layers 40D and 40E can be prevented or reduced.

It is noted that, although only the insulator layer 60-1 corresponding to the conductor layers 39E-1 and 40E-1 among the plurality of insulator layers 60 is illustrated in the cross section illustrated in FIG. 4, the present disclosure is not limited thereto. The semiconductor memory device 1 may include the two or more insulator layers 60 in an XZ plane, according to the corresponding number of the conductor layers 39E and 40E.

With the above configuration, each of the conductor layers 40E is separated from the first surface of the circuit chip 1-1 by an insulator layer 60 corresponding to the conductor layer 40E. In addition, the plurality of insulator layers 60 are in contact with the first surfaces of the plurality of insulator layers 58, respectively.

The insulator layer 55 is provided on the first surfaces of the insulator layer 59 and the plurality of conductor layers 40B, 40D, and 40E. The insulator layer 55 comprises, for example, silicon oxide. In the insulator layer 55, the plurality of conductor layers 41 and 42 and a portion of the memory cell array 10 are provided.

The memory cell array 10 is provided so that the conductor layer 34 is located on the semiconductor substrate 70 side and the conductor layer 30A is located on the electrode pad PD side. The memory cell array 10 is, for example, provided so that the second surface of the conductor layer 30A is located at the same height as the first surface of the insulator layer 55. That is, the conductor layers 31, 33, 34, and 35, the eight conductor layers 32, the insulator layers 50, 51, and 53, the eight insulator layers 52, the members SHE, as well as portions of the plurality of memory pillars MP, and the like of the memory cell array 10 are provided in the insulator layer 55.

The plurality of conductor layers 41 include the conductor layers 41-1, 41-2, 41-3, 41-4, and 41-5.

The conductor layer 41-1 is provided on the first surface of the conductor layer 40B-1. The conductor layer 41-1 functions as a columnar contact. The first surface of the conductor layer 41-1 is connected to the second surface of the conductor layer 34. Accordingly, the bit line BL is electrically connected to the transistor Tr1 via the conductor layers 36-1, 37-1, 38-1, 39B-1, 40B-1, and 41-1.

The conductor layer 41-2 is provided on the first surface of the conductor layer 40B-2. The conductor layer 41-2 functions as a columnar contact. The conductor layer 41-2 penetrates the insulator layer 55 in the Z direction.

The conductor layer 41-3 is provided on the first surface of the conductor layer 40B-3. The conductor layer 41-3 functions as a columnar contact. The conductor layer 41-3 penetrates the insulator layer 55 in the Z direction.

The conductor layer 41-4 is provided on the first surface of the conductor layer 40B-4. The conductor layer 41-4 functions as a columnar contact.

The conductor layer 41-5 is provided on the first surface of the conductor layer 40E-1. The conductor layer 41-5 functions as a columnar contact.

The conductor layer 42 connecting the conductor layers 41-4 and 41-5 is provided on the first surfaces of the conductor layers 41-4 and 41-5. With such a configuration, the conductor layer 40E-1 is electrically connected to the transistor Tr4 via the conductor layers 36-4, 37-4, 38-4, 39B-4, 40B-4, 41-4, 42, and 41-5.

The conductor layer 30A provided in the memory cell array 10 includes the portion that is provided, for example, on the first surface of the insulator layer 50 of the memory cell array 10, on the first surfaces of the plurality of memory pillars MP, and on the first surface of the insulator layer 55.

The conductor layer 30B is provided on the first surface of the insulator layer 55 in the same layer as the conductor layer 30A. The conductor layers 30A and 30B are separated from each other.

The conductor layer 43 is provided on the electrode pad PD side in the Z direction than the insulator layer 55. The conductor layer 43 functions as a wiring layer. The conductor layer 43 comprises, for example, aluminum. The conductor layer 43 extends along the X direction. The conductor layer 43 includes portions C1, C2, and J. The portions C1, J, and C2 are arranged in this order along the X direction. The portion C1 is in contact with the first surface of the conductor layer 41-2 and a region of the first surface of the insulator layer 55 surrounding the first surface of the conductor layer 41-2. The portion C2 is in contact with at least a portion of the first surface of the conductor layer 30A. The portion J electrically connects the portions C1 and C2 on the electrode pad PD side in the Z direction than the first surface of the conductor layer 30A. With such a configuration, the source line SL is electrically connected to the transistor Tr2 via the conductor layers 36-2, 37-2, 38-2, 39B-2, 40B-2, 41-2, and 43.

The conductor layer 44 is in contact with the first surface of the conductor layer 41-3 and the region of the first surface of the insulator layer 55 surrounding the first surface of the conductor layer 41-3. The conductor layer 44 functions as an electrode pad PD. The electrode pads PD can be connected to a mounting substrate, an external device, or the like by, for example, bonding wires, solder balls, metal bumps, or the like. The electrode pads PD comprise, for example, copper. With such a configuration, the electrode pad PD can be electrically connected to the transistor Tr3 via the conductor layers 36-3, 37-3, 38-3, 39B-3, 40B-3, and 41-3.

In regions on the first surfaces of the insulator layer 55 and the conductor layers 30A and 30B that are not in contact with the conductor layers 43 and 44, for example, up to the height of the second surface of the portion J of the conductor layer 43, the insulator layer 54 is provided. The insulator layer 54 comprises, for example, silicon oxide. The insulator layer 54 electrically insulates between conductor layers 30A and 30B, between conductor layers 30A and 44, between conductor layers 30B and 43, between conductor layers 30B and 44, and between conductor layers 43 and 44.

The first surface of the conductor layer 43, the first surface of the conductor layer 44, and regions of the first surface of the insulator layer 54 not in contact with the conductor layers 43 and 44 are provided with the insulator layer 61, except for the portions functioning as the electrode pads PD on the first surface of the conductor layer 44. The insulator layer 61 functions as a passivation film. The insulator layer 61 comprises, for example, silicon nitride, a resin material, or the like.

In the above configuration, conductor layer 39E, insulator layer 58, insulator layer 60, and conductor layer 40E are arranged in this order in the 22 direction. The conductor layer 39E, the conductor layer 40E, and the insulator layers 58 and 60 therebetween function as a capacitive element. The conductor layers 39E and 40E are electrode pads EP functioning as electrodes of these capacitive elements. In addition, insulator layers 58 and insulator layers 60 are interposed between two electrode pads EP in the Z direction. These capacitive elements can be used as elements in, for example, the peripheral circuits such as the command register 11, the address register 12, the sequencer 13, the driver module 14, the row decoder module 15, and the sense amplifier module 16. The capacitive element including the conductor layers 39E-1 and 40E-1 and the insulator layers 58-1 and 60-1 is provided between the transistors Tr4 and Tr5 in the peripheral circuit, for example, in the configuration described above.

It is noted that the conductor layers 39D and 40D are dummy pads DP that do not function as electrodes. The plurality of dummy pads DP form the dish-shaped structure on the circuit chip 1-1 side and the dish-shaped structure on the memory chip 1-2 side in manufacturing of the semiconductor memory device 1.

### 1.1.5.2 Structure of Bonding Pad and Capacitive Element

### [Structure in XY Plane]

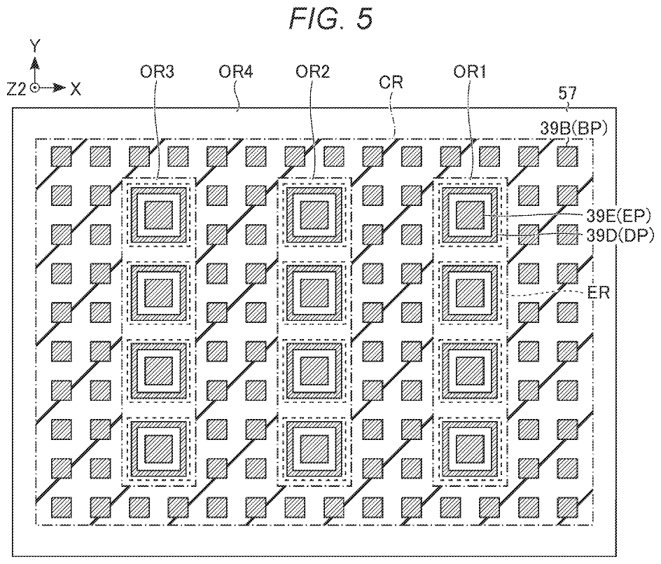

The structure of the bonding pads BP and the capacitive elements provided in the same layer as the bonding pad BP will be described with reference to FIG. 5. FIG. 5 is a cross-sectional view of the semiconductor memory device at the same height as the line V-V along the Z direction in FIG. 4, illustrating an example of the cross-sectional structure of the semiconductor memory device 1 according to the embodiment in the XY plane. FIG. 5 illustrates the cross-sectional structure of the entire semiconductor memory device 1.

In the cross section illustrated in FIG. 5, the semiconductor memory device 1 is divided into a region CR and a plurality of regions OR. In FIG. 5, the region CR is the hatched region enclosed by dot-long-dash lines.

The region CR is where the plurality of conductor layers 39B are provided. In the region CR, for example, the plurality of conductor layers 39B and the second portion of the insulator layer 57 are provided. The second portion of the insulator layer 57 is a portion different from the first portion of the insulator layer 57. The second portion of the insulator layer 57 surrounds each of the plurality of conductor layers 39B. Accordingly, each of the plurality of conductor layers 39B is separated from the other conductor layers 39B and the plurality of conductor layers 39D and 39E in the same layer.

The plurality of regions OR are those regions outside of (excluded from) the region CR. The regions OR are where the plurality of conductor layers 39D and 39E are provided.

The plurality of regions OR include regions OR1, OR2, OR3, and OR4. Each region OR1, OR2, and OR3 is surrounded by the region CR. Each of the regions OR1, OR2, and OR3 is provided, for example, in a rectangular shape having sides parallel to the X direction and sides parallel to the Y direction. The region OR4 is a region surrounding the region CR.

Each region OR1, OR2, and OR3 includes a plurality of regions ER. The regions ER correspond to each of the plurality of conductor layers 39D and 39E, respectively. The conductor layers 39D and 39E are provided in each of the regions ER. The conductor layer 39D of a region ER is provided so as to surround the conductor layer 39E of the region ER in a ring shape. The size of each of the conductor layers 39D can be set according to the size of the conductor layer 39E corresponding to the conductor layer 39D. The first portion of the insulator layer 57 is provided between the conductor layers 39D and 39E in the regions ER to separate the conductor layers 39D and 39E. With such a configuration, each of the plurality of conductor layers 39D is electrically insulated from the conductor layer 39E corresponding to the conductor layer 39D by a portion of insulator layer 57.

For example, four regions ER are arranged in the Y direction within each of the regions OR1, OR2, and OR3. That is, in each of the regions OR1, OR2, and OR3, four sets of conductor layers 39D and 39E are arranged in the Y direction. Each of the regions ER is separated from the adjacent regions ER by a third portion of the insulator layer 57. The third portion of the insulator layer 57 is different from the first and second portions of the insulator layer 57.

It is noted that, although the example illustrated in FIG. 5 illustrates the case where the semiconductor memory device 1 includes one region CR, the embodiment is not limited thereto. The semiconductor memory device 1 may include the two or more regions CR.

In addition, although the example illustrated in FIG. 5 illustrates the case where the semiconductor memory device 1 includes the three regions OR1, OR2, and OR3 surrounded by a region CR, the embodiment is not limited thereto. The semiconductor memory device 1 may include no regions OR surrounded by a region CR, or any number of regions OR surrounded by a region CR.

In addition, in the example illustrated in FIG. 5, although the case where each of the regions OR1, OR2, and OR3 has a rectangular shape is illustrated, the embodiment is not limited to this shape. Each of the regions OR1, OR2, and OR3 may be provided, for example, in other polygonal shapes.

In addition, although the example illustrated in FIG. 5 illustrates the case where the conductor layers 39D and 39E are not provided in the region OR4, the embodiment is not limited thereto. The region OR4 may be provided with the one or more conductor layers 39D and 39E.

In addition, in the example illustrated in FIG. 5, although the four conductor layers 39E (four regions ER) are arranged in the Y direction in each of the regions OR1, OR2, and OR3, the embodiment is not limited thereto. The conductor layers 39E may be arranged in the X direction, and the number of the conductor layers 39E arranged in the X and Y directions may be any number. In addition, the arrangement of the plurality of conductor layers 39E in each of the regions OR can be freely selected. For example, in each of the plurality of regions OR, the conductor layers 39E may be provided in a grid pattern. That is, the two or more conductor layers 39E may be arranged in each of the X direction and the Y direction.

In addition, in the example illustrated in FIG. 5, a case is illustrated in which the sizes of the plurality of conductor layers 39E are the same when viewed in the Z direction, but the embodiment is not limited thereto. The sizes of the plurality of conductor layers 39E may be different from each other when viewed in the Z direction.

In addition, although specific illustration is omitted, the cross-sectional structure in the XY plane including the plurality of conductor layers 40B, 40D, and 40E and the insulator layer 59 is substantially the same as the cross-sectional structure illustrated in FIG. 5. In addition, when viewed from above, the size of each of the plurality of conductor layers 39E and the size of the conductor layer 40E corresponding to the conductor layer 39E are, for example, approximately the same.

### [Structure on XZ Plane]

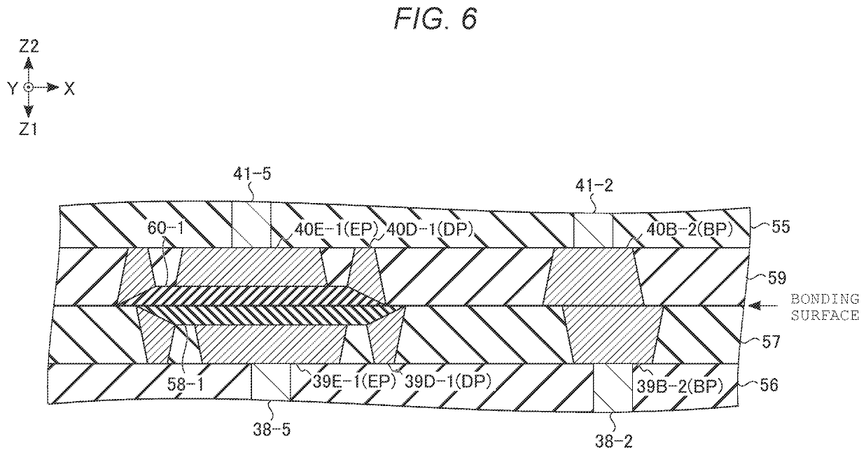

Next, the cross-sectional structure of the bonding pad BP and the capacitive element provided in the same layer as the bonding pad BP in the XZ plane will be described with reference to FIG. 6. FIG. 6 is a cross-sectional view illustrating an example of the cross-sectional structure in the XZ plane of the bonding pads and the capacitive element provided in the semiconductor memory device 1 according to an embodiment.

It is noted that, in the following, the cross-sectional structure of the portion of the bonding pad BP to which the conductor layers 39B-2 and 40B-2 are connected will be described. However, the same description applies to the cross-sectional structure of each of the plurality of other conductor layers 39B and the portion to which the conductor layer 40B corresponding to the conductor layer 39B is connected.

In addition, the cross-sectional structure of the capacitive element including the conductor layers 39E-1 and 40E-1 and the insulator layers 58-1 and 60-1 will be described below. However, the same description applies to the cross-sectional structure of the capacitive element including each of the plurality of other conductor layers 39E, the conductor layer 40E corresponding to the conductor layer 39E, and the insulator layers 58 and 60.

On the bonding surface where the circuit chip 1-1 and the memory chip 1-2 are bonded together, the area of the conductor layer 39B-2 and the area of the conductor layer 40B-2 are, for example, approximately the same. In the conductor layers 39B-2 and 40B-2, in the XZ plane, the first surface, the side surface, and the second surface of the cross-sectional structure including the conductor layers 39B-2 and 40B-2 can be covered with a barrier metal. Each of the conductor layers 39B-2 and 40B-2 is formed by, for example, a damascene method. In this case, the side surface of the conductor layer 39B-2 has a taper shape that is tapered toward the Z1 direction. In addition, the side surface of the conductor layer 40B-2 has a taper shape that is tapered toward the Z2 direction.

The second surface and the side surfaces of the conductor layer 39E-1 can be covered with a barrier metal in the XZ plane. In addition, the first surface and the side surfaces of the conductor layer 40E-1 can be covered with a barrier metal in the XZ plane. The conductor layers 39E-1 and 40E-1 are formed by, for example, a damascene method, similarly to the conductor layers 39B-2 and 40B-2. In this case, the side surface of the conductor layer 39E-1 has a taper shape that is tapered toward the Z1 direction, similarly to the conductor layer 39B-2. In addition, the side surface of the conductor layer 40E-1 has a taper shape that is tapered toward the Z2 direction, similarly to the conductor layer 40B-2.

The second surface and the side surface of the conductor layer 39D-1 can be covered with a barrier metal in the XZ plane. The first surface and the side surface of the conductor layer 40D-1 can be covered with a barrier metal in the XZ plane. The conductor layers 39D-1 and 40D-1 are formed by, for example, a damascene method, similarly to the conductor layers 39B-2 and 39E-1 and the conductor layers 40B-2 and 40E-1. In this case, each of the side surfaces of the conductor layer 39D-1 of the portion on the one end side and the portion on the other end side along the X direction has a taper shape to be tapered toward the Z1 direction, similarly to the conductor layers 39B-2 and 39E-1. In addition, each of the side surfaces of the conductor layer 40D-1 of the portion on the one end side and the portion on the other end side along the X direction has a taper shape to be tapered toward the 22 direction, similarly to the conductor layers 40B-2 and 40E-1.

With the above configuration, the integration of the conductor layers 39B-2 and 40B-2 may cause the identification of a boundary between the conductor layers 39B-2 and 40B-2 to be difficult. However, even in such a case, bonding of the conductor layers 39B-2 and 40B-2 can be checked by distortion of the cross-sectional structure including the conductor layers 39B-2 and 40B-2 due to misalignment in bonding. In addition, the bonding of the conductor layers 39B-2 and 40B-2 can be checked by a discontinuity location generated, for example, by misalignment of the barrier metal on the side surface of the conductor layer 39B-2 and the barrier metal on the side surface of the conductor layer 40B-2.

When each of the side surface of the conductor layer 39B-2 and the side surface of the conductor layer 40B-2 has a taper shape, the boundary formed by the side surface of the conductor layer 39B-2 and the side surface of the conductor layer 40B-2 in the XZ plane does not have a linear shape. For this reason, the cross-sectional structure including the conductor layers 39B-2 and 40B-2 has a non-rectangular shape regardless of whether there is misalignment in bonding. Therefore, the bonding of the conductor layers 39B-2 and 40B-2 can be checked.

When the barrier metal is formed as described above, the second surface of the conductor layer 39B-2, the side surface of the conductor layer 39B-2, the side surface of the conductor layer 40B-2, and the first surface of the conductor layer 40B-2 are covered with a barrier metal in the XZ plane. On the other hand, for a general wiring layer using copper, an insulator layer (silicon nitride, silicon carbide containing nitrogen, or the like) having a function of preventing oxidation of copper is usually provided on the upper surface of copper, and no barrier metal is provided. For this reason, even when there is no misalignment in bonding, it can be possible to distinguish the wiring layer obtained by the integration of the conductor layers 39B-2 and 40B-2 from a general wiring layer. It is noted that, although not specifically illustrated in FIG. 6, the cross-sectional structure of the portion where the conductor layer 39B and the conductor layer 40B are connected and the cross-sectional structure of the capacitive element including the conductor layers 39E and 40E and the insulator layers 58 and 60 in the YZ plane can also be the same as the cross-sectional structures for the XZ plane illustrated in FIG. 6.

### 1.2 Method for Manufacturing Semiconductor Memory Device

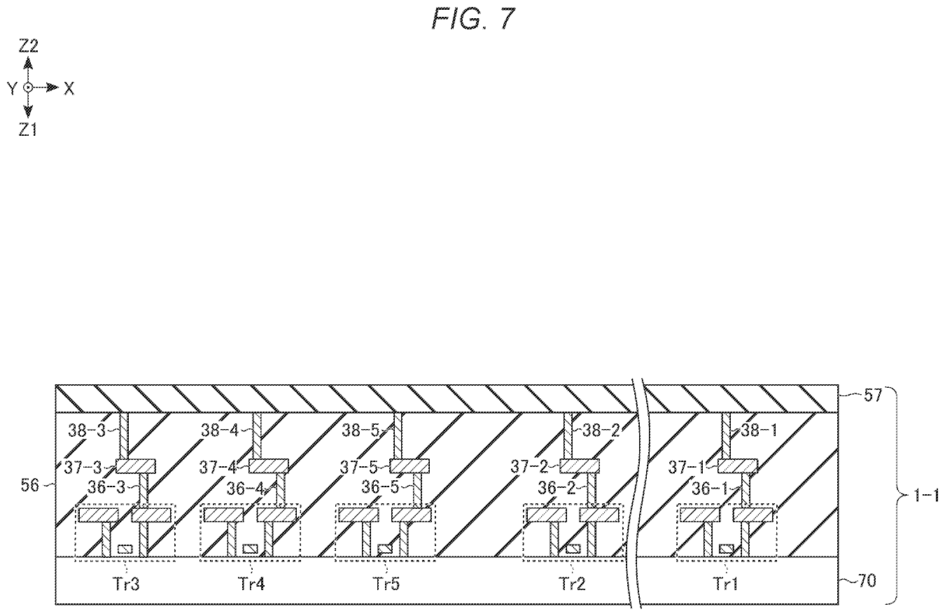

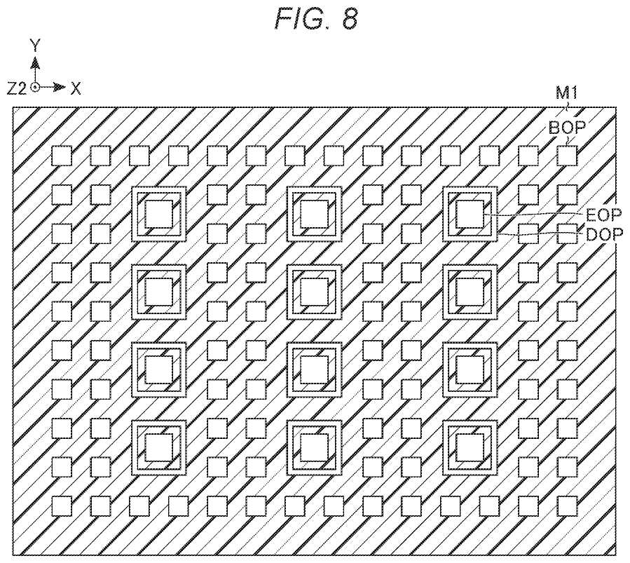

A method for manufacturing the semiconductor memory device 1 will be described with reference to FIGS. 7 to 15. FIGS. 7 and 9 to 15 are cross-sectional views illustrating an example of the method for manufacturing the semiconductor memory device according to the embodiment. The cross-sectional views illustrated in FIGS. 7 and 9 to 15 correspond to the regions illustrated in FIG. 4. FIG. 8 is a top view illustrating an example of the method for manufacturing the semiconductor memory device according to the embodiment. The top view illustrated in FIG. 8 is a view for illustrating a mask for forming the regions illustrated in FIG. 5.

First, as illustrated in FIG. 7, the transistors Tr1, Tr2, Tr3, Tr4, and Tr5 and the conductor layers 36, 37, and 38 are formed on the first surface of the semiconductor substrate 70. In addition, the insulator layer 56 is formed up to the same height as the first surfaces of the plurality of conductor layers 38 so as to bury the transistors Tr1, Tr2, Tr3, Tr4, and Tr5, and the plurality of conductor layers 36, 37, and 38. In addition, the insulator layer 57 is formed on the first surfaces of the plurality of conductor layers 38 and the first surface of the insulator layer 56.

Next, as illustrated in FIG. 8, a mask M1 having a plurality of openings BOP, EOP, and DOP is formed on the first surface of the insulator layer 57. The plurality of openings BOP, EOP, and DOP are provided corresponding to the plurality of bonding pads BP, the plurality of electrode pads EP, and the plurality of dummy pads DP, respectively. Accordingly, each of the plurality of openings DOP surrounds an opening EOP corresponding to the opening DOP.

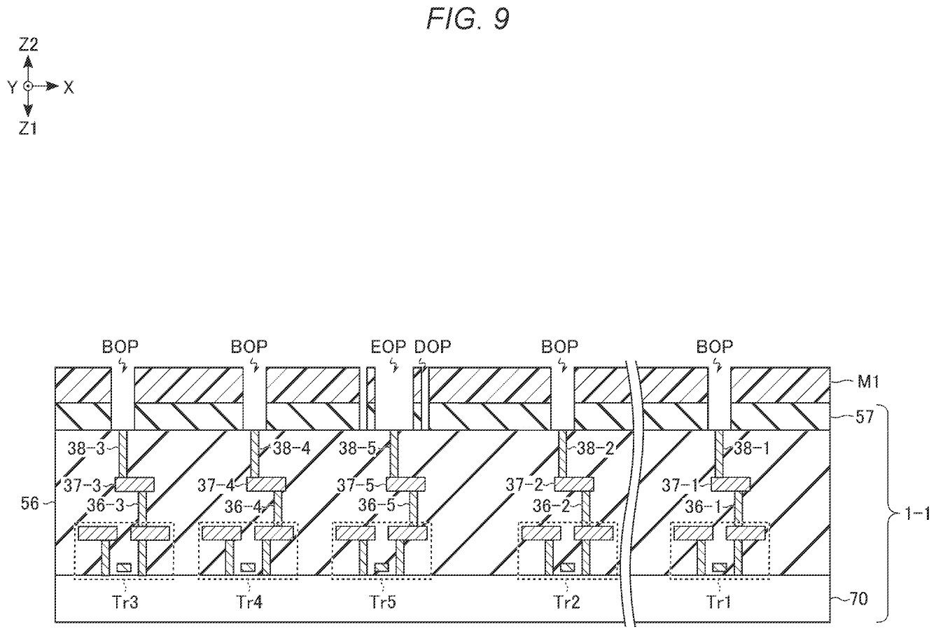

Then, as illustrated in FIG. 9, the regions of the insulator layer 57 corresponding to the plurality of bonding pads BP, the plurality of electrode pads EP, and the plurality of dummy pads DP are removed by anisotropic etching using the formed mask M1. The anisotropic etching in this process is, for example, reactive ion etching (RIE). After that, the mask M1 is removed.

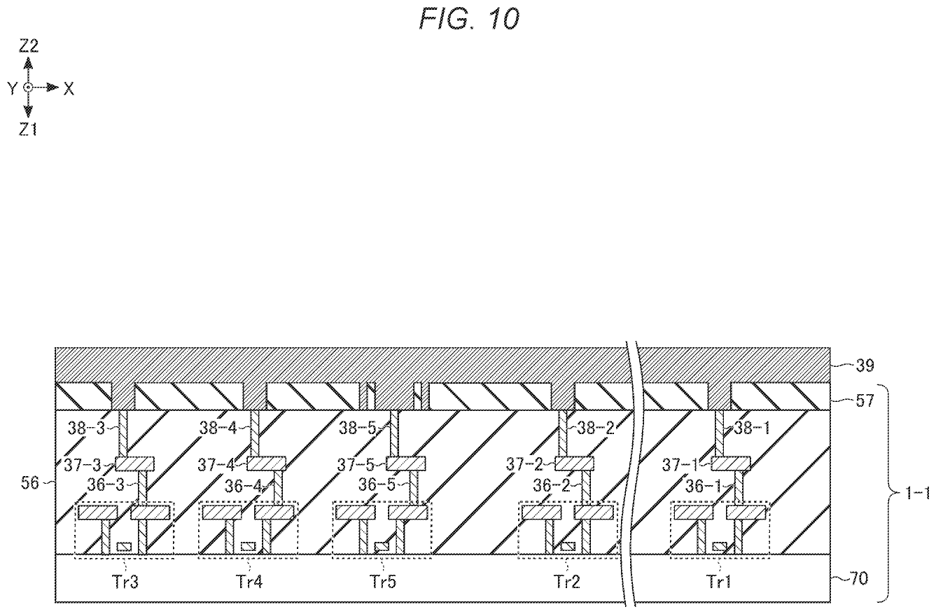

Then, as illustrated in FIG. 10, the conductor layer 39 is formed on the first surface of the insulator layer 57 and so as to fill the space from which portions of insulator layer 57 were removed by the anisotropic etching using the mask M1.

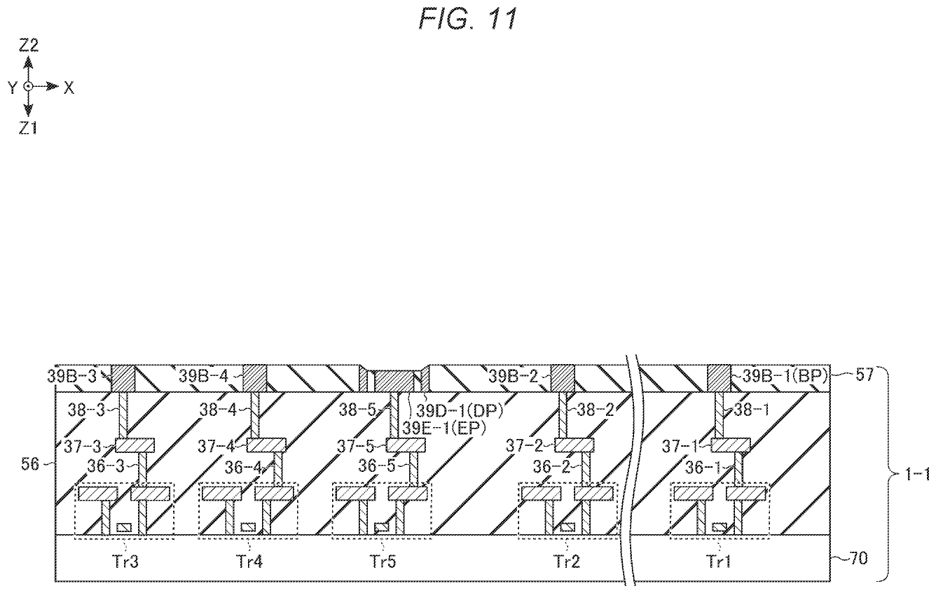

Next, as illustrated in FIG. 11, the portion of the conductor layer 39 on the first end side is removed by, for example, chemical mechanical polishing (CMP). Accordingly, the plurality of conductor layers 39B, 39D, and 39E are formed. In this process, dishing and erosion occur in the portions of the conductor layer 39 formed in the openings EOP and DOP and the portions of the insulator layer 57 between openings EOP and the surrounding openings DOP. A dish-shaped structure recessed toward the semiconductor substrate 70 (in which the insulator layer 58 can be later be filled) is formed by such dishing and erosion. As in the semiconductor memory device 1 according to the embodiment, when the dummy pads DP corresponding to the electrode pads EP surround each of the plurality of electrode pads EP, in this process, dishing and erosion can be generated so that the first surfaces of the plurality of electrode pads EP are sufficiently recessed to be closer to the semiconductor substrate 70 than is the first surface of the bonding pad BP.

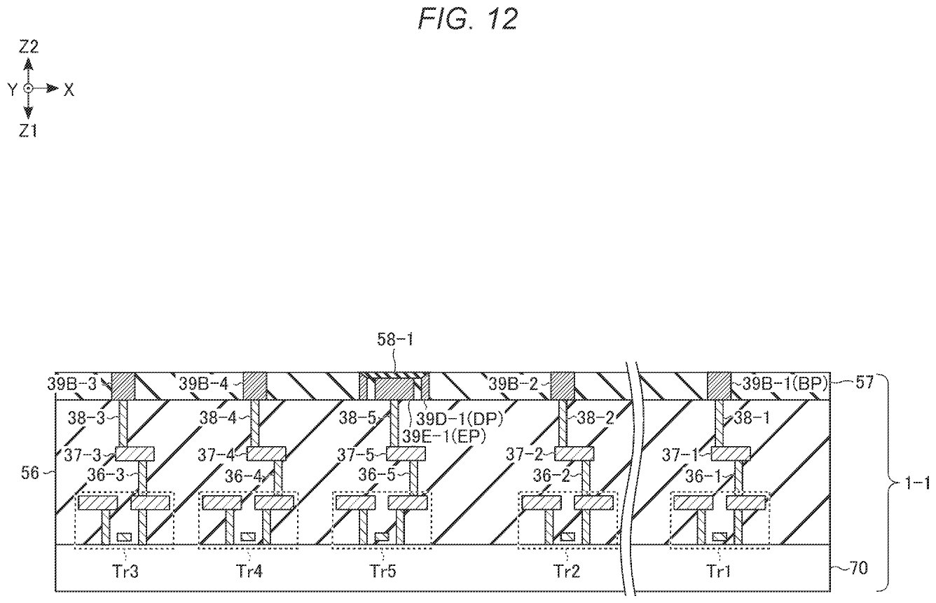

The insulator material is then deposited on the first surfaces of the insulator layer 57 and the plurality of conductor layers 39B, 39D, and 39E. Then, the excess portion of the deposited insulator in the Z direction is removed by, for example, CMP. Accordingly, as illustrated in FIG. 12, the plurality of insulator layers 58 are formed.

Through the above process, the circuit chip 1-1 is formed.

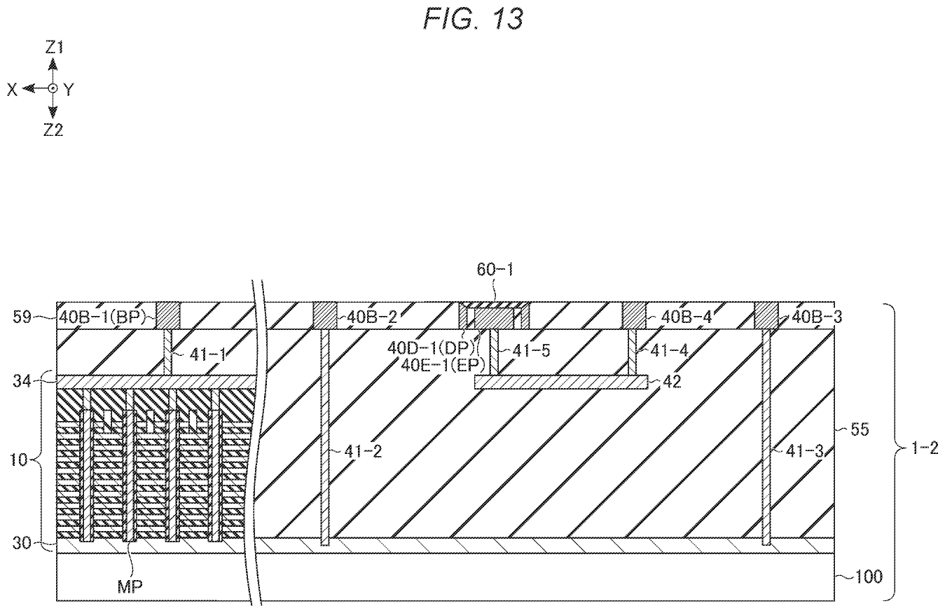

Next, as illustrated in FIG. 13, the conductor layer 30, the portion of the memory cell array 10 excluding the conductor layer 30A, the plurality of conductor layers 40B, 40D, 40E, and 41, the conductor layer 42, the insulator layers 55 and 59, and the plurality of insulator layers 60 are formed on the second surface of a semiconductor substrate 100. The conductor layer 30 includes the portions corresponding to the conductor layers 30A and 30B. Through this process, a portion of the memory chip 1-2 is formed. It is noted that the process of forming the plurality of conductor layers 40B, 40D, and 40E, the insulator layer 59, and the plurality of insulator layers 60 is substantially the same as the process of forming the plurality of conductor layers 39B, 39D, and 39E, the insulator layer 57, and the plurality of insulator layers 58 described with reference to FIGS. 8 to 12.

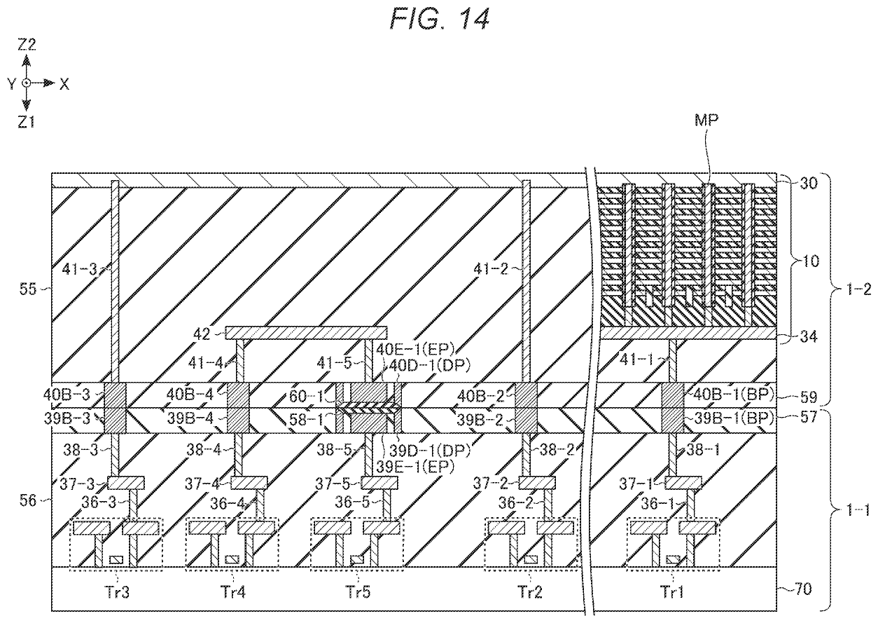

Then, as illustrated in FIG. 14, a bonding process of the circuit chip 1-1 and the memory chip 1-2 and a removing of the semiconductor substrate 100 are performed. More specifically, the plurality of conductor layers 39B provided in the circuit chip 1-1 and functioning as bonding pads BP and the plurality of conductor layers 40B provided in the memory chip 1-2 and functioning as bonding pads BP are positioned to face each other. In addition, the bonding pads BP facing each other are joined by a heat treatment (thermal process). By such a bonding process, the plurality of conductor layers 39E provided in the circuit chip 1-1 and functioning as electrodes of the capacitive elements and the plurality of conductor layers 40E provided in the memory chip 1-2 and functioning as electrodes of the capacitive elements are arranged in the Z direction via the plurality of insulator layers 58 and 60. After that, the semiconductor substrate 100 is removed.

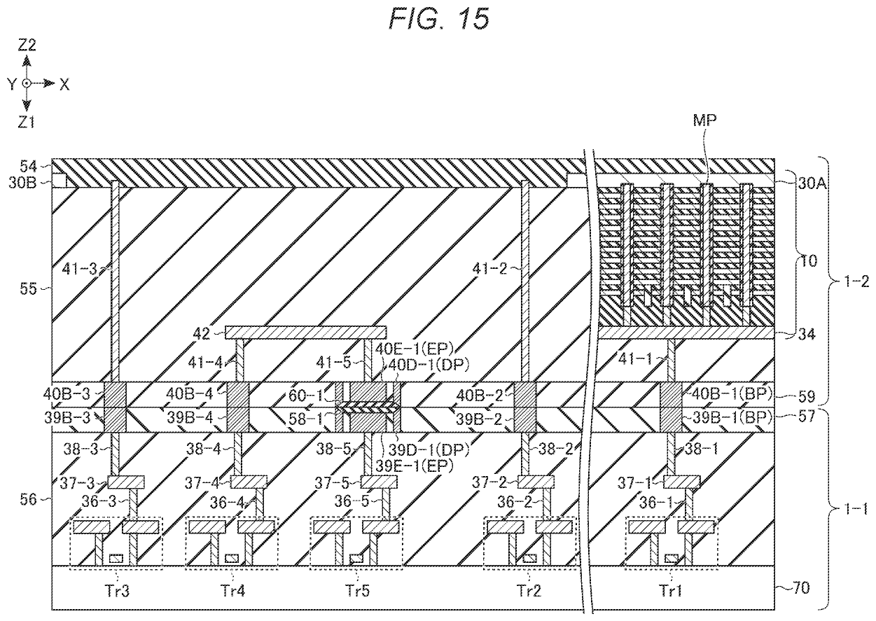

The conductor layers 30A and 30B and the insulator layer 54 are then formed as illustrated in FIG. 15. More specifically, the conductor layer 30 is separated into the conductor layers 30A and 30B by, for example, a process using lithography and etching. In addition, the insulator is deposited on the first surfaces of the conductor layers 30A and 30B, the portion of the first surface of the insulator layer 55 where the conductor layers 30A and 30B are not provided, and the first surfaces of the conductor layers 41-2 and 41-3.

The conductor layers 43 and 44 and the insulator layer 61 are then formed. Accordingly, the semiconductor memory device 1 illustrated in FIG. 4 is formed. More specifically, the region of the insulator layer 54, where the portions C1 and C2 of the conductor layer 43 and the portion to which the conductor layer 44 and the conductor layer 41-3 are connected are scheduled to be formed is removed by, for example, a process using lithography and etching. Then, the conductor is formed on the first surfaces of the conductor layers 41-2 and 41-3, the first surface of the portion of the conductor layer 30A, the first surface of the insulator layer 54, and the portion of the first surface of the insulator layer 55, surrounding the conductor layers 41-2 and 41-3 so that the thickness, for example, along the Z direction is approximately uniform. Then the formed conductor is separated into the conductor layers 43 and 44 by, for example, a process using lithography and etching. In addition, the insulator layer 61 is formed except for at least a portion of the conductor layer 44 functioning as the electrode pad PD.

It is noted that the manufacturing method described above is merely an example, and other processes may be inserted between these processes, and the order of the processes may be changed. For example, since the circuit chip 1-1 and the memory chip 1-2 are formed by using the different semiconductor substrates 70 and 100, the processes of forming the circuit chip 1-1 illustrated in FIGS. 7 to 12 and the processes of forming the portion of the memory chip 1-2 illustrated in FIG. 13 may proceed in parallel.

### 1.3 Effect

According to the embodiment, an increase in the size of the semiconductor memory device 1 can be prevented. Effects of the embodiment will be described below.

The semiconductor memory device 1 includes a circuit chip 1-1 and a memory chip 1-2. The semiconductor memory device 1 includes the plurality of conductor layers 39B provided on the circuit chip 1-1 and the plurality of conductor layers 40B which are provided on the memory chip 1-2 and in which the lower surface is in contact with the upper surface of the plurality of conductor layers 39B in a boundary region between the circuit chip 1-1 and the memory chip 1-2. In addition, the semiconductor memory device 1 includes the plurality of conductor layers 39E. The plurality of conductor layers 39E and the plurality of conductor layers 39B are arranged in the same layer as the plurality of conductor layers 39B. In addition, the semiconductor memory device 1 includes the plurality of conductor layers 40E. The plurality of conductor layers 40E and the plurality of conductor layers 40B are arranged in the same layer as the plurality of conductor layers 40B. The plurality of conductor layers 39E and the plurality of conductor layers 40E are provided corresponding to each other. Each of the plurality of conductor layers 39E and the conductor layer 40E corresponding to the conductor layer 39E are separated from each other in the Z direction. In addition, the semiconductor memory device 1 includes the plurality of insulator layers 58 and 60 in the boundary regions between the circuit chip 1-1 and the memory chip 1-2. The plurality of insulator layers 58 and 60 are provided corresponding to the plurality of conductor layers 39E and 40E. Each of the conductor layers 39E and the conductor layer 40E corresponding to the conductor layer 39E are disposed such that the insulator layers 58 and 60 are interposed therebetween in the Z direction. With such a configuration, the plurality of conductor layers 39E and 40E and the plurality of insulator layers 58 and 60 form a plurality of capacitive elements in the boundary regions between the circuit chip 1-1 and the memory chip 1-2. Accordingly, the capacitive element can be formed above the semiconductor substrate 70 instead of being formed on the semiconductor substrate 70. For this reason, an increase in the number of elements formed on the semiconductor substrate 70 and an increase in the size of the semiconductor substrate 70 are prevented. Therefore, an increase in the size of the semiconductor memory device 1 can be prevented.

In addition, the arrangement of the capacitive elements can be more easily performed, as compared to the case where the capacitive elements are provided in the insulator layer 55 and the case where the capacitive elements are provided in the insulator layer 56. Supplementally, the wirings provided in the insulator layer 56 can be arranged so that the electrical connection in the circuit chip 1-1 becomes more efficient when electrically connecting the circuit chip 1-1 and the memory chip 1-2. In addition, the wirings provided in the insulator layer 55 can be located so that the electrical connection in the memory chip 1-2 becomes more efficient, similarly to the wirings provided in the insulator layer 56. For these reasons, the wirings provided in the insulator layers 55 and 56 can be located in a more complicated or advantageous manner. When a capacitive element is provided in the insulator layer 55 or in the insulator layer 56, there is a possibility that it may be difficult to allocate a region for the capacitive element in view of the other wiring pattern constraints. On the other hand, the plurality of conductor layers 39B and 40B functioning as the bonding pads BP are more simply located as compared to the wirings provided within the insulator layers 55 and 56, for example, in order to facilitate the bonding of the circuit chip 1-1 and the memory chip 1-2. With the semiconductor memory device 1, since the plurality of conductor layers 39E and 40E are provided in the same layer as the plurality of conductor layers 39B and 40B, it is typically not difficult to allocate a region for the capacitive elements.

In addition, the semiconductor memory device 1 includes a plurality of conductor layers 39D that surround the plurality of conductor layers 39E and function as dummy pads DP in the XY plane. According to such a configuration, as described for the process illustrated in FIG. 11, a dish-shaped structure (in which the plurality of insulator layers 58 can be filled) is formed in the same process as the plurality of conductor layers 39B, 39D, and 39E by dishing and erosion that typically results from the manufacturing process. Accordingly, there is no need to perform a process different from the process of forming the plurality of conductor layers 39B, 39D, and 39E in order to form the dish-shaped structure in which the plurality of insulator layers 58 can be filled (embedded). In addition, similarly to the dish-shaped structure in which the insulator layers 58 can be filled, a dish-shaped structure in which the plurality of insulator layers 60 can be filled is formed in the same process as the plurality of conductor layers 40B, 40D, and 40E. For these reasons, it is possible to prevent a decrease in yield of the semiconductor memory device 1 by requiring additional process steps or the like.

In addition, for the semiconductor memory device 1, each of the plurality of conductor layers 39D surrounds a conductor layer 39E in a ring shape. With such an arrangement of the conductor layers 39D, dishing and erosion in CMP in the process shown in FIG. 11 of the manufacturing method can be efficiently generated while preventing an increase in the area occupied by the plurality of conductor layers 39D. In addition, similarly, for the plurality of conductor layers 40D and 40E, while preventing an increase in the area of the plurality of conductor layers 40D, dishing and erosion by the CMP in the process of forming the portion of the memory chip 1-2 can be efficiently generated. With these configurations an increase in the size of the semiconductor memory device 1 can be prevented.

### 2. MODIFIED EXAMPLES

Various modified examples are possible for the above-described embodiment.

### 2.1 Modified Example 1

In an above-described embodiment, the case where each electrode pad EP is surrounded by one dummy pad DP when viewed in the Z direction is illustrated, but the present disclosure is not limited thereto. The semiconductor memory device 1 may be configured so that each of the electrode pads EP is surrounded by a plurality of dummy pads DP when viewed in the Z direction.

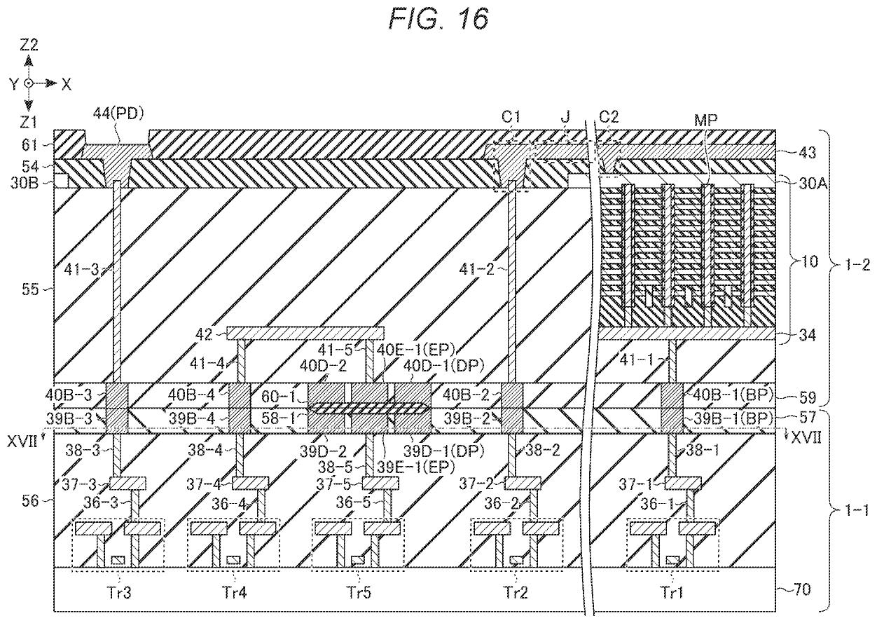

The cross-sectional structure of the semiconductor memory device 1 according to Modified Example 1 will be described with reference to FIG. 16. FIG. 16 is a cross-sectional view illustrating an example of the cross-sectional structure of the semiconductor memory device according to Modified Example 1 in the XZ plane. FIG. 16 corresponds to the cross-sectional structure of the semiconductor memory device according to the embodiment illustrated in FIG. 4.

The structure of the circuit chip 1-1 will be described.

In the XZ plane, each of the conductor layers 39E is interposed between the two conductor layers 39D each corresponding to the conductor layer 39E. FIG. 16 illustrates only the two conductor layers 39D-1 and 39D-2 between which the conductor layer 39E-1 is interposed in the X direction. In the XZ plane, each of the conductor layers 39E is separated from the two conductor layers 39D corresponding to the conductor layer 39E by a first portion of the insulator layer 57.

In the cross section illustrated in FIG. 16, each of the first surfaces of the two conductor layers 39D has a recessed portion on the conductor layer 39E side in the X direction. Accordingly, the first surfaces of the conductor layer 39E, the recessed portions of the two conductor layers 39D corresponding to the conductor layer 39E, and the first portion of the insulator layer 57 form a dish-shaped structure.

It is noted that, although not specifically illustrated in FIG. 16, a similar dish-shaped recessed structure is formed in the YZ plane.

The structure of the memory chip 1-2 will be described.

In the XZ plane, each of the conductor layers 40E is interposed between two corresponding conductor layers 40D. FIG. 16 illustrates only the two conductor layers 40D-1 and 40D-2 between which the conductor layer 40E-1 is interposed in the X direction. In the XZ plane, each of the conductor layers 40E is separated from the two conductor layers 40D by a portion of the insulator layer 59.

In the cross section illustrated in FIG. 16, second surfaces of recessed portions of the two conductor layers 40D, the corresponding conductor layer 40E and the portion of the insulator layer 59 form a dish-shaped structure similarly to the dish-shaped structure of the circuit chip 1-1.

It is noted that, although not specifically illustrated in FIG. 16, a similar dish-shaped recessed structure is formed in the YZ plane.

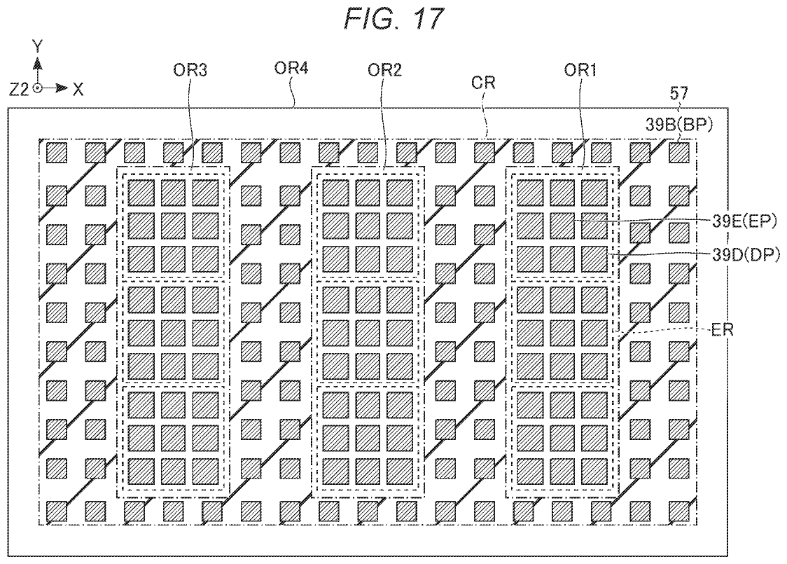

Next, the structure of the bonding pad BP and the capacitive element provided in the same layer as the bonding pad BP will be described with reference to FIG. 17. FIG. 17 is a cross-sectional view of the semiconductor memory device at the same height as line XVII-XVII along the Z direction in FIG. 16, illustrating an example of the cross-sectional structure of the semiconductor memory device according to Modified Example 1 in the XY plane. FIG. 17 corresponds to the cross-sectional structure of the entire semiconductor memory device according to the embodiment illustrated in FIG. 5.

FIG. 17 illustrates an example in which the three regions ER are arranged in the Y direction in each of the regions OR1, OR2, and OR3. That is, the three conductor layers 39E are arranged in the Y direction in each of the regions OR1, OR2, and OR3. However, the number and arrangement of the plurality of regions ER and the plurality of conductor layers 39E are not limited thereto. The number and arrangement of the plurality of regions ER and the plurality of conductor layers 39E may be any number and arrangement.

A plurality of conductor layers 39D and a conductor layer 39E are provided in each of the plurality of regions ER. In the example illustrated in FIG. 17, the eight conductor layers 39D are provided in each of the regions ER. The size of each of the conductor layers 39D is, for example, the same as the size of each of the plurality of conductor layers 39E.

In each of the regions ER, the eight conductor layers 39D surround the conductor layer 39E corresponding to the region ER. In each of the regions ER, the eight conductor layers 39D and the conductor layer 39E are arranged in a grid pattern or the like. It is noted that, although not specifically illustrated, in each region ER, each conductor layer 39D has, for example, a portion of which the upper end is located closer to the semiconductor substrate 70 than the upper surface of the circuit chip 1-1 on the side adjacent to the conductor layer 39E.

It is noted that, although the example illustrated in FIG. 17 illustrates that the eight conductor layers 39D are provided in each of the regions ER, the number of the conductor layers 39D provided in each of the regions ER is not limited to eight. The plurality of conductor layers 39D may be provided in the regions ER so as to surround the conductor layer 39E of the region ER and the number of conductor layers 39D provided in each of the regions ER may be any number of two or more.

In addition, in the example illustrated in FIG. 17, each of the plurality of conductor layers 39D and 39E has a square shape, and the case where the size of each of the plurality of conductor layers 39D is the same as the size of each of the plurality of conductor layers 39E is illustrated. With such sizes and shapes of the plurality of conductor layers 39D and 39E, the arrangement of the plurality of conductor layers 39D and 39E can be simplified. Accordingly, it is possible to prevent the arrangement of the plurality of conductor layers 39D and 39E from becoming complicated and causing the manufacturing process to be difficult.

However, the sizes and shapes of the plurality of conductor layers 39D and 39E are not limited to the sizes and shapes described above. For example, the size of each of the conductor layers 39D may be different from the size of each of the conductor layers 39E. In addition, the sizes within the plurality of conductor layers 39D may be different. In addition, the shape of the conductor layers 39D and 39E is not limited to a square shape and may be a rectangular shape elongated in the X direction or the Y direction.

In each of the regions ER, the first portion of the insulator layer 57 is provided between the conductor layer 39E and each of the conductor layers 39D in the region ER and between adjacent conductor layers 39D in the plurality of conductor layers 39D in the region ER. Accordingly, in each of the plurality of regions ER, the conductor layer 39E is separated from each of the plurality of conductor layers 39D. In addition, in each of the plurality of regions ER, the conductor layers 39D are separated from each other.

In addition, although specific illustration is omitted, the cross-sectional structure including the plurality of conductor layers 40B, 40D, and 40E and the insulator layer 59 can be substantially the same as the cross-sectional structure illustrated in FIG. 17.

In the method for manufacturing the semiconductor memory device 1 according to Modified Example 1, differences from the method for manufacturing the semiconductor memory device according to the embodiment will be described.

In the semiconductor memory device 1 according to Modified Example 1, the plurality of conductor layers 39D are provided in each of the regions ER. Accordingly, in a process corresponding to FIG. 11, dishing and erosion occur in the portion corresponding to the plurality of openings DOP and EOP in the conductor layer 39 formed so as to fill the space formed by the anisotropic etching using the mask M1, in the portion of the insulator layer 57 provided between each of the openings EOP and the openings DOP surrounding the openings EOP, and in the portions of the insulator layer 57 arranged between the two adjacent openings DOP among the plurality of openings DOP. Accordingly, a dish-shaped structure recessed toward the semiconductor substrate 70 is formed. Even with the arrangement of the dummy pads DP of Modified Example 1, dishing and erosion can occur in this process so that the first surfaces of the plurality of electrode pads EP are sufficiently located closer to the semiconductor substrate 70 than the first surfaces of the bonding pads BP.

According to Modified Example 1, it is possible to prevent an increase in the size of the semiconductor memory device 1. In addition, according to Modified Example 1, it is not difficult to allocate the region for locating the capacitive element. In addition, according to Modified Example 1, it is possible to prevent the decrease in the manufacturing yield of the semiconductor memory device 1.

### 2.2 Modified Example 2

In the embodiment and Modified Example 1 described above, the plurality of conductor layers 39D, which are the dummy pads DP, are provided in the same layer as the plurality of conductor layers 39E, but the present disclosure is not limited thereto. The semiconductor memory device may not include the dummy pads DP in the same layer as the plurality of conductor layers 39E. In the following description according to Modified Example 2, differences from the previously described embodiments and examples will be mainly described.

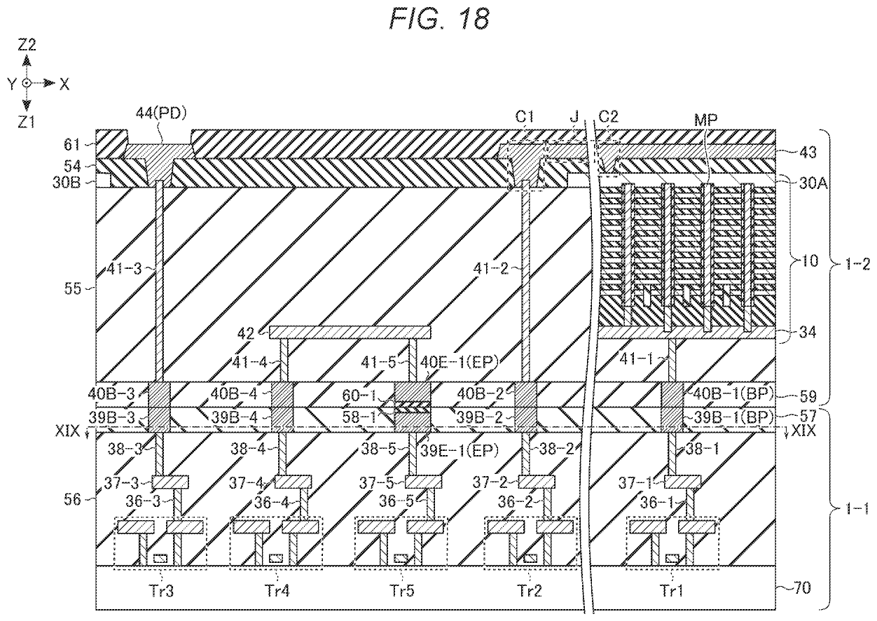

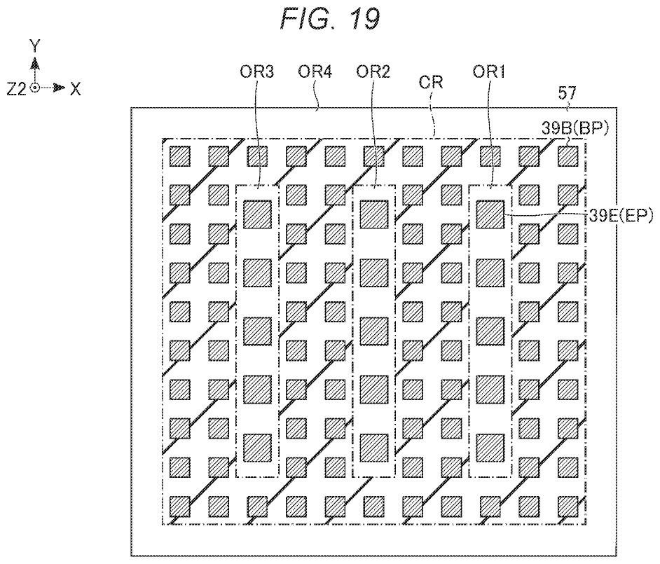

A cross-sectional structure of the semiconductor memory device 1 according to Modified Example 2 will be described with reference to FIGS. 18 and 19. FIG. 18 is a cross-sectional view illustrating an example of the cross-sectional structure of the semiconductor memory device according to Modified Example 2 in the XZ plane. FIG. 19 is a cross-sectional view illustrating an example of the cross-sectional structure of the semiconductor memory device according to Modified Example 2 in the XY plane. FIG. 19 is a cross-sectional view of the semiconductor memory device at the same height as line XIX-XIX along the Z direction in FIG. 18. FIG. 18 corresponds to the cross-sectional structure illustrated in FIGS. 4 and 16. FIG. 19 corresponds to the cross-sectional structure illustrated in FIGS. 5 and 17.

As illustrated in FIG. 18, the semiconductor memory device 1 does not include the plurality of conductor layers 39D in the circuit chip 1-1.

The first surface of the insulator layer 57 is flush with the first surface of the circuit chip 1-1.

The first surface of each of the conductor layers 39E and the side surfaces of portions of the insulator layer 57 surrounding the conductor layers 39E form a structure recessed toward the semiconductor substrate 70 side. Each of the insulator layers 58 is provided so as to fill the recessed structure on the semiconductor substrate 70 side.

In the memory chip 1-2, the semiconductor memory device 1 does not include the plurality of conductor layers 40D.

The second surface of insulator layer 59 is flush with the second surface of the memory chip 1-2.

The second surfaces of the plurality of conductor layers 40E and the side surfaces of the portions of the insulator layer 59 surrounding the conductor layers 40E form a structure recessed toward the electrode pad PD. Each of the insulator layers 60 is provided so as to fill the recessed structure on the electrode pad PD side.

As illustrated in FIG. 19, in the XY plane, the structure of the semiconductor memory device 1 is the same as the structure of the semiconductor memory device according to the embodiment illustrated in FIG. 5 in the XY plane except that the plurality of conductor layers 39D are not included.

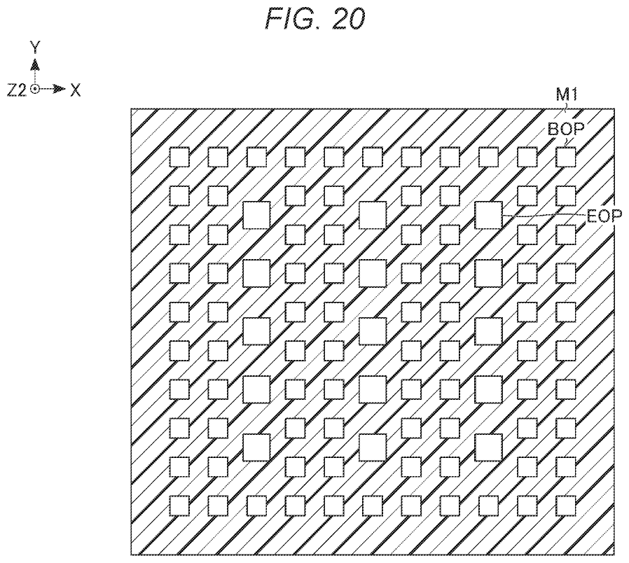

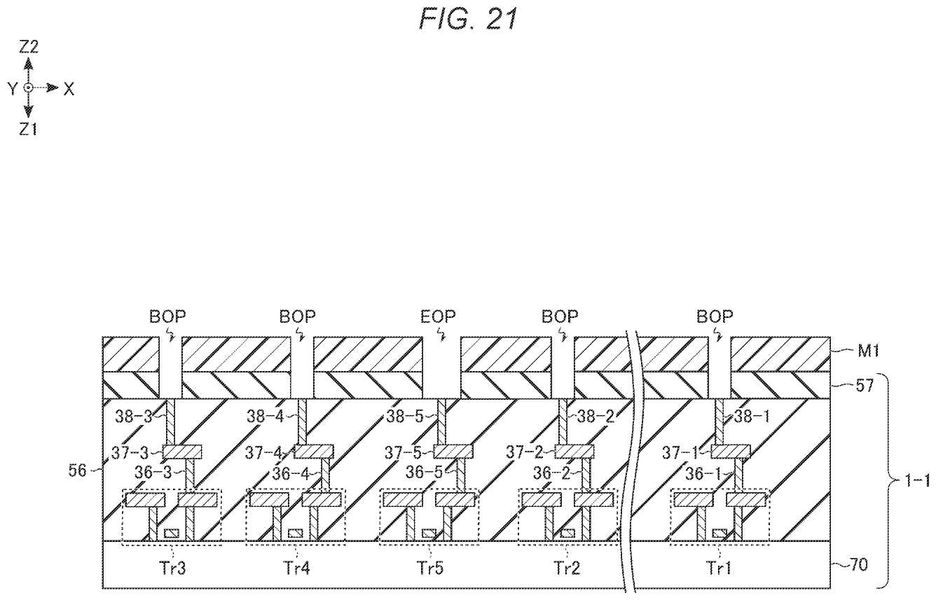

Next, a method for manufacturing the semiconductor memory device 1 according to Modified Example 2 will be described with reference to FIGS. 20 to 25. FIG. 20 is a top view illustrating an example of the method for manufacturing the semiconductor memory device according to Modified Example 2. FIG. 20 is a diagram illustrating a mask for forming a region corresponding to FIG. 19. FIGS. 21 to 25 are cross-sectional views illustrating an example of the method for manufacturing the semiconductor memory device according to Modified Example 2. The cross-sectional views illustrated in FIGS. 21 to 25 correspond to the region illustrated in FIG. 18.

In forming the circuit chip 1-1, the transistors Tr1, Tr2, Tr3, Tr4, and Tr5, the plurality of conductor layers 36, 37, and 38, and the insulator layers 56 and 57 are formed similarly to the process described in conjunction with FIG. 7.

Next, as illustrated in FIG. 20, a mask M1 having a plurality of openings BOP and EOP is formed on the first surface of the insulator layer 57 formed. The plurality of openings BOP and EOP are provided corresponding to the plurality of bonding pads BP and the plurality of electrode pads EP, respectively.

Then, as illustrated in FIG. 21, the region corresponding to the bonding pads BP and the electrode pads EP of the insulator layer 57 are removed by the anisotropic etching using the formed mask M1 in the same manner as in the process illustrated in conjunction with FIG. 9.

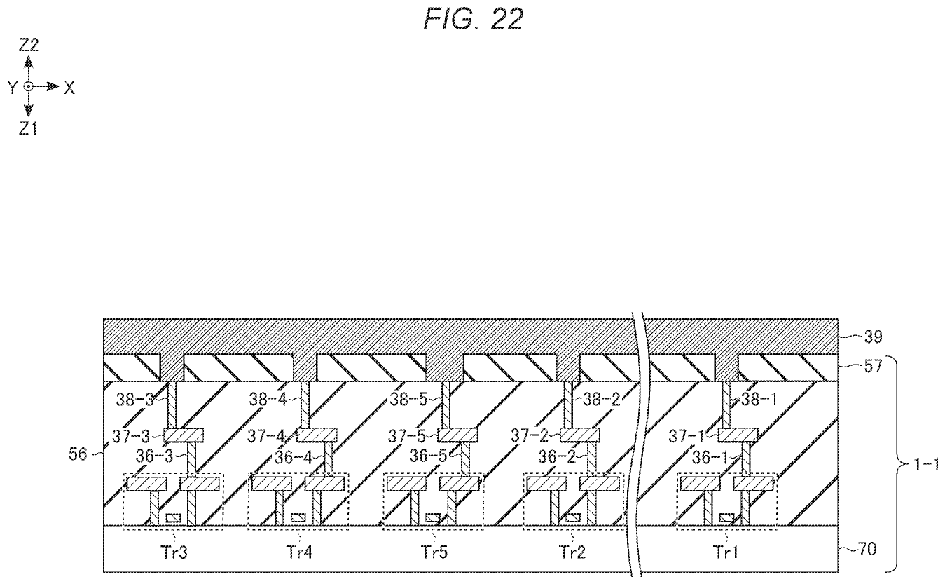

Then, as illustrated in FIG. 22, a conductor layer 39 is formed similarly to the process described in conjunction with FIG. 10.

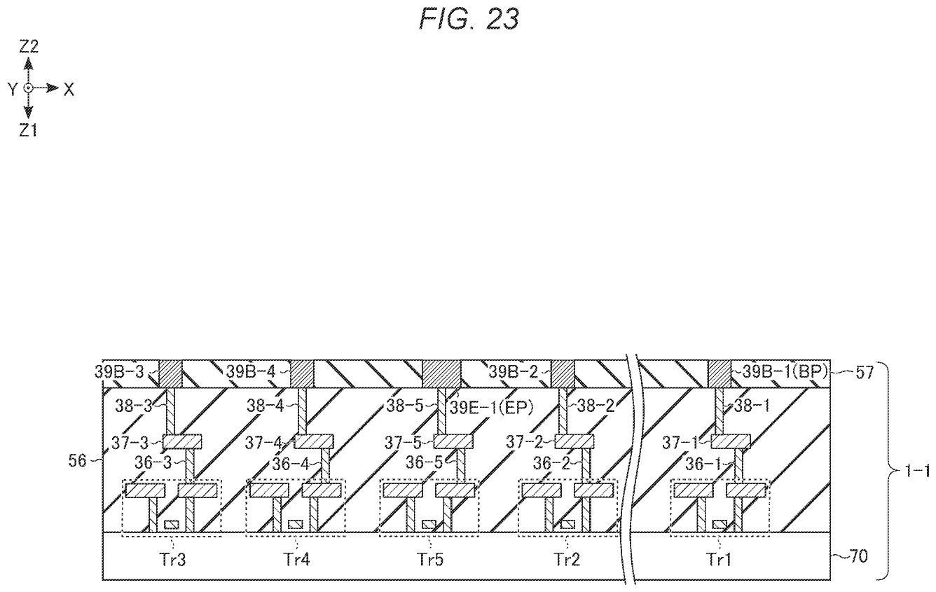

Next, as illustrated in FIG. 23, the excess portion of the conductor layer 39 is removed by, for example, CMP. Accordingly, the plurality of conductor layers 39B and 39E are formed. It is noted that in the semiconductor memory device 1 according to Modified Example 2, unlike the embodiment and Modified Example 1, dummy pads are not located around each of the plurality of electrode pads EP. For this reason, dishing and erosion do not occur in this process.

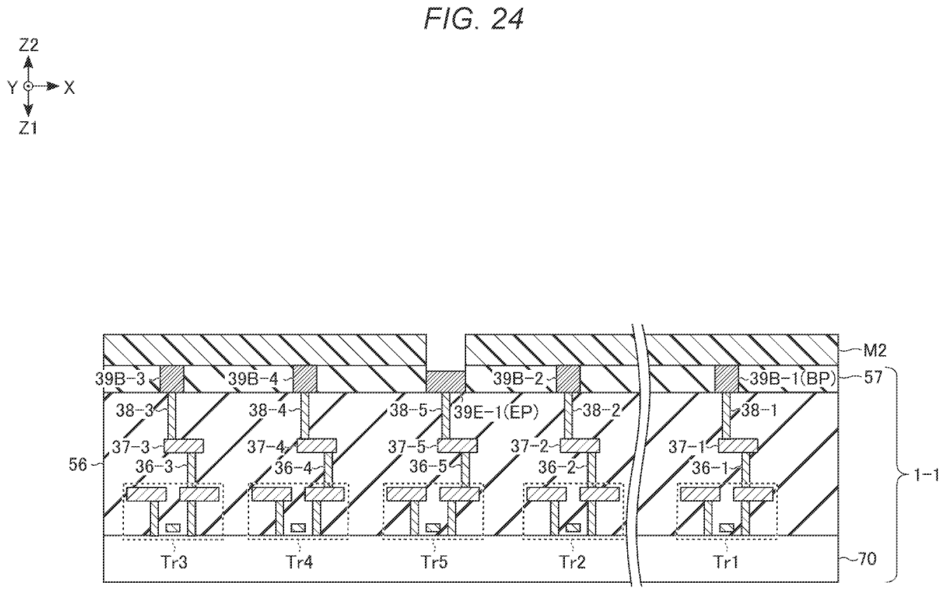

Then, a mask M2 having openings corresponding to the plurality of conductor layers 39E is formed on the first surfaces of the plurality of conductor layers 39B and the insulator layer 57. Then, as illustrated in FIG. 24, portions of the conductor layers 39E on the first end side (upper surface) are removed by anisotropic etching using the formed mask M2. Through this process, the first surfaces of the conductor layers 39E are recessed to be closer to the semiconductor substrate 70 than the first surfaces of the plurality of conductor layers 39B. A structure recessed toward the semiconductor substrate 70 formed by the first surfaces of the plurality of conductor layers 39E and the side surfaces of the first portion of the insulator layer 57 surrounding the conductor layers 39E is obtained.

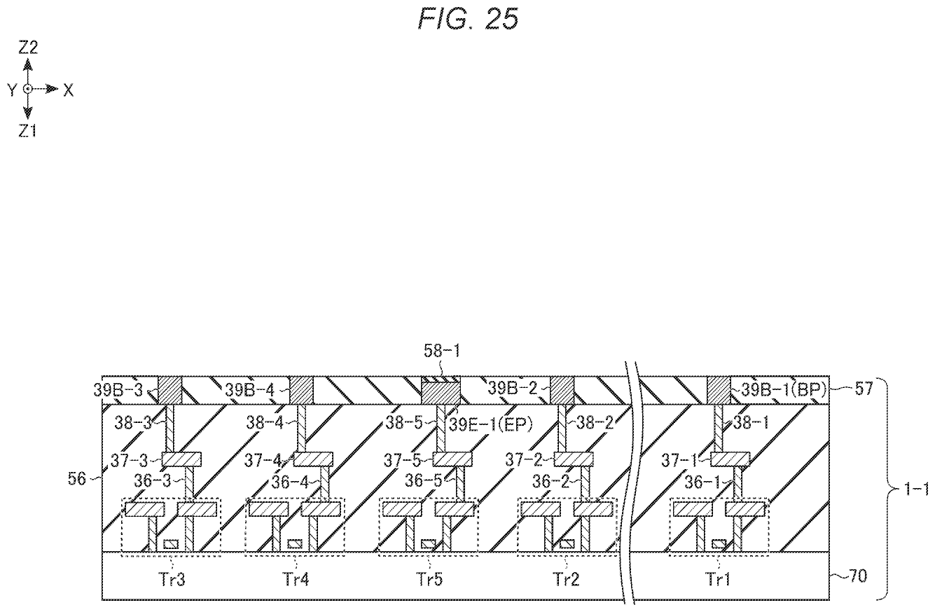

Then, an insulator material is deposited on the first surfaces of the insulator layer 57 and the plurality of conductor layers 39B and 39E. Next, an excess portion of the deposited insulator in the Z direction is removed by, for example, CMP. Accordingly, the plurality of insulator layers 58 are formed as illustrated in FIG. 25.

Through the above processes, the circuit chip 1-1 is formed.

Next, the conductor layer 30, a portion of the memory cell array 10 excluding the conductor layer 30A, the plurality of conductor layers 40B, 40E, and 41, the conductor layer 42, and the insulator layers 55 and 59, and the plurality of insulator layers 60 are formed on the second surface of the semiconductor substrate 100. Through this process, a portion of the memory chip 1-2 is formed. It is noted that the process of forming the plurality of conductor layers 40B and 40E, the insulator layer 59, and the plurality of insulator layers 60 are substantially the same as the process for forming the plurality of conductor layers 39B and 39E, the insulator layer 57, and the plurality of insulator layers 58 described with reference to FIGS. 20 to 25.

Other processes are the same as those of the method for manufacturing the semiconductor memory device 1 according to the embodiment.

According to Modified Example 2, it is possible to prevent an increase in the size of the semiconductor memory device 1 similarly to the embodiment and Modified Example 1. In addition, according to Modified Example 2, similarly to the embodiment and Modified Example 1, it is not difficult to allocate the region for locating the capacitive element.

In addition, according to Modified Example 2, it is not necessary to provide dummy pads around the plurality of conductor layers 39E. With such a configuration, an increase in the size of the semiconductor memory device 1 can be prevented.

### 2.3 Modified Example 3

A case where the size of each of the plurality of conductor layers 39E and the size of the conductor layer 40E corresponding to the conductor layer 39E are the same as each other has been described, but the present disclosure is not limited thereto. The size of each of the plurality of conductor layers 39E may be different from the size of the conductor layer 40E corresponding to each conductor layer 39E. It is noted that, the method for manufacturing the semiconductor memory device 1 according to Modified Example 3 may be the same as the method for manufacturing the semiconductor memory device 1 according to Modified Example 2, the description thereof will be omitted.

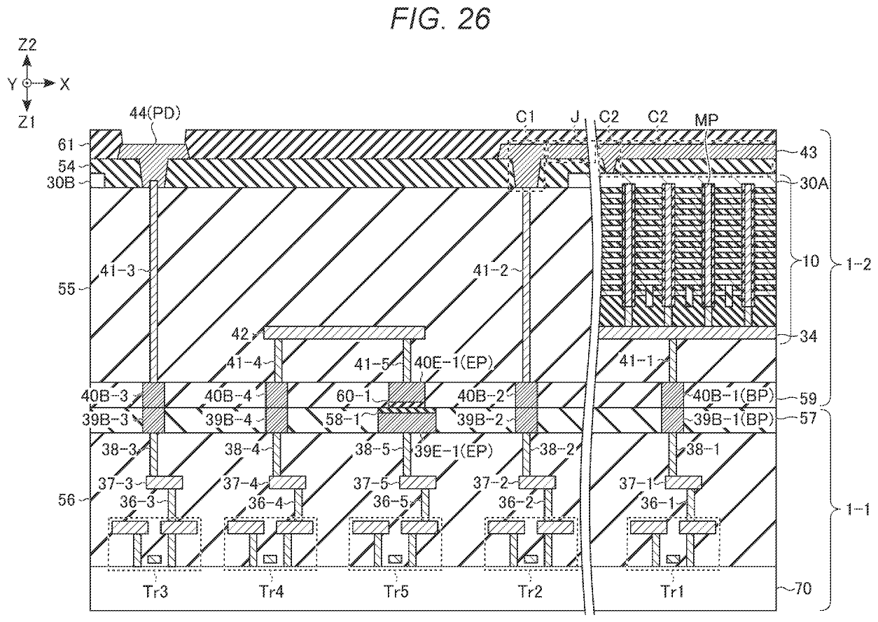

A configuration of the semiconductor memory device 1 according to Modified Example 3 will be described with reference to FIG. 26. FIG. 26 is a cross-sectional view illustrating an example of the cross-sectional structure of the semiconductor memory device according to Modified Example 3 in the XZ plane. FIG. 26 corresponds to the cross-sectional structure of the semiconductor memory device illustrated in FIGS. 4, 16, and 18.

In Modified Example 3, the conductor layer 39E and the conductor layer 40E corresponding to the conductor layer 39E have different sizes when viewed from above. For example, the size of each of the plurality of conductor layers 39E is larger than the size of the conductor layer 40E corresponding to the conductor layer 39E. Accordingly, as illustrated in FIG. 26, the length of the conductor layer 39E-1 along the X direction is greater than the length of the conductor layer 40E-1 along the X direction. It is noted that, in the example illustrated in FIG. 26, the case where the size of the conductor layer 39E-1 is larger than the size of the conductor layer 40E-1 is illustrated, but the present disclosure is not limited thereto. In other examples, the size of conductor layers 39E may be different from the size of the conductor layer 40E corresponding to the conductor layer 39E. For example, the conductor layers 39E may be smaller than the conductor layer 40E corresponding to the conductor layer 39E.

The size of each of the plurality of insulator layers 58 is, for example, the same as the size of the conductor layer 39 corresponding to the insulator layer 58 when viewed from above. The size of each of the plurality of insulator layers 60 is, for example, the same as s the size of the conductor layer 40 corresponding to that insulator layer 60. Accordingly, when the size of each of the plurality of conductor layers 39E is larger than the size of the conductor layer 40E corresponding to the conductor layer 39E, the size of the insulator layer 58 corresponding to the conductor layer 39E is, for example, larger than the size of the insulator layer 60 corresponding to the conductor layer 40E. In addition, when the size of each of the plurality of conductor layers 39E is smaller than the size of the conductor layer 40E corresponding to the conductor layer 39E, the size of the insulator layer 58 corresponding to the conductor layer 39E is, for example, smaller than the size of the insulator layer 60 corresponding to the conductor layer 40E.

The Modified Example 3 also provides the same effect as Modified Example 2.

In addition, according to Modified Example 3, the size of each of the plurality of conductor layers 39E can be different from the size of the corresponding conductor layer 40E. Accordingly, it is possible to prevent a change in capacitance of the capacitive element due to any misalignment of the circuit chip 1-1 and the memory chip 1-2 during the bonding process of the manufacturing method.

It is noted that Modified Example 3 may be combined with the other described examples. That is, in the embodiment and Modified Example 1, the sizes of the conductor layers 39E may be different from the corresponding conductor layers 40E. In such cases, the method for manufacturing the semiconductor memory device may be adapted according to the embodiment and Modified Example 1.

### 2.4 Modified Example 4

A case where both the insulator layers 58 and 60 are provided has been illustrated as an example, but the present disclosure is not limited thereto. The semiconductor memory device 1 may include either of the insulator layers 58 or insulator layers 60. In the following description, in the configuration and the manufacturing method of the semiconductor memory device 1 according to Modified Example 4, differences from the configuration and manufacturing method of the semiconductor memory device according to Modified Example 2 will be mainly described.

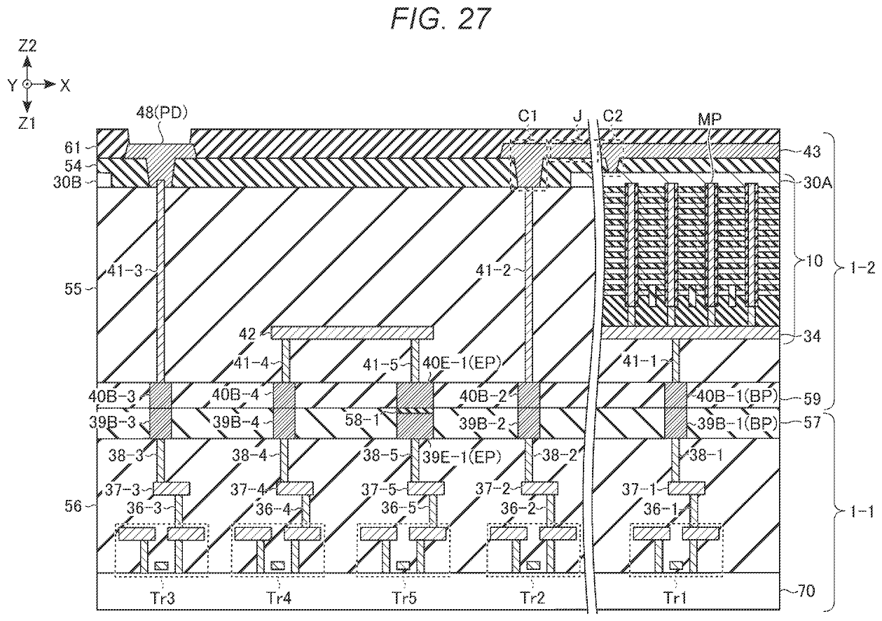

A configuration of the semiconductor memory device 1 according to Modified Example 4 will be described with reference to FIG. 27. FIG. 27 is a cross-sectional view illustrating an example of the cross-sectional structure of the semiconductor memory device according to Modified Example 4 in the XZ plane. FIG. 27 corresponds to the cross-sectional structure of the semiconductor memory device illustrated in FIGS. 4, 16, 18, and 26.

In the example illustrated in FIG. 27, the second surfaces of the plurality of conductor layers 40E provided in the memory chip 1-2 are located at the same heights as the second surfaces of the plurality of conductor layers 40B. Accordingly, the second surfaces of the plurality of conductor layers 40E are flush with the second surface of the memory chip 1-2. In other words, the semiconductor memory device 1 does not include the plurality of insulator layers 60. The second surfaces of the plurality of conductor layers 40E are in contact with the first surfaces of the insulator layers 58 corresponding to the conductor layers 40E.

In the above configuration, each of the conductor layers 39E, the conductor layer 40E corresponding to the conductor layer 39E, and the insulator layer 58 interposed between the conductor layers 39E and 40E form a capacitive element.

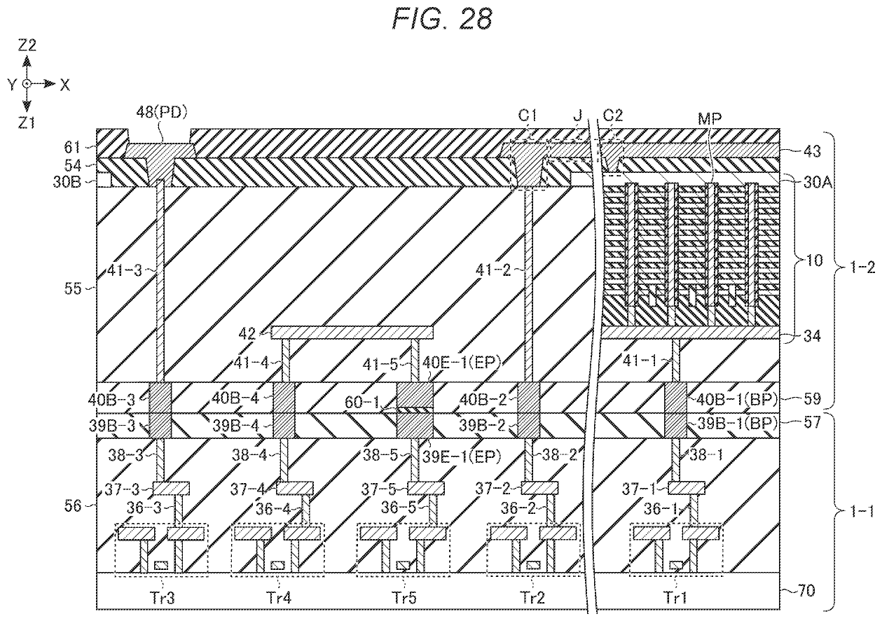

It is noted that, in the example illustrated in FIG. 27, the case where the semiconductor memory device 1 includes the plurality of insulator layers 58 is described, but the present disclosure is not limited thereto. The semiconductor memory device 1 may instead include, for example, the plurality of insulator layers 60 as illustrated in FIG. 28. FIG. 28 is a cross-sectional view illustrating an example of the cross-sectional structure of the semiconductor memory device according to Modified Example 4 in the XZ plane. In the example illustrated in FIG. 28, among the plurality of insulator layers 60, only the insulator layer 60-1 corresponding to the conductor layers 39E-1 and 40E-1 is illustrated. In this case, in the circuit chip 1-1, the first surfaces of the plurality of conductor layers 39E are located at the same heights as the first surfaces of the plurality of conductor layers 39B. Accordingly, the first surfaces of the plurality of conductor layer 39E are flush with the first surface of the circuit chip 1-1. That is, the semiconductor memory device 1 does not include the plurality of insulator layers 58. The first surfaces of the plurality of conductor layers 39E are in contact with the second surfaces of the insulator layers 60 corresponding to the conductor layers 39E.

In this case, each of the conductor layers 39E, the conductor layer 40E corresponding to the conductor layer 39E, and the insulator layer 60 interposed between the conductor layers 39E and 40E form a capacitive element.

Next, a method for manufacturing the semiconductor memory device 1 according to Modified Example 4 will be described.

When the semiconductor memory device 1 does not include the plurality of insulator layers 60, the method for manufacturing the circuit chip 1-1 is the same as the method for manufacturing the semiconductor memory device 1 according to Modified Example 2 and Modified Example 3.

In addition, in this case, the method for manufacturing the portion of the memory chip 1-2 is the same as the method for manufacturing the portion of the memory chip 1-2 of the semiconductor memory device 1 according to Modified Example 2 and Modified Example 3 except that the process for forming the plurality of insulator layers 60 is not performed.

When the semiconductor memory device 1 does not include the plurality of insulator layers 58, the method for manufacturing the portion of the circuit chip 1-1 is the same as the method for manufacturing the portion of the circuit chip 1-1 of the semiconductor memory device 1 according to Modified Example 2 and Modified Example 3 except that the process of forming the plurality of insulator layers 58 is not performed.

In addition, in this case, the method for manufacturing the memory chip 1-2 is the same as the method for manufacturing the semiconductor memory device 1 according to Modified Example 2 and Modified Example 3.

The Modified Example 4 also has the same effect as Modified Example 2.

In addition, according to Modified Example 4, the insulator provided in the capacitive element is formed only in one of the circuit chip 1-1 and the memory chip 1-2. Accordingly, a decrease in the yield of the semiconductor memory device 1 can be prevented.

In addition, Modified Example 4 may be combined with another modified example. That is, in the embodiment, Modified Example 1, and Modified Example 3, the semiconductor memory device 1 may not include one or the other of the insulator layers 58 and insulating layers 60. When the embodiment or Modified Example 1 is combined with Modified Example 4, for example, among the circuit chip 1-1 and the memory chip 1-2, a chip that does not include the plurality of insulator layers functioning as insulators for the capacitive elements may not be provided with the plurality of conductor layers corresponding to the dummy pads DP. In this case, the same effects as those of the embodiment or Modified Example 1 are obtained.

### 3. OTHERS

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a first chip including a substrate;
a second chip in contact with the first chip, the second chip including a memory cell array with a plurality of first wiring layers separated from each other in a first direction perpendicular to an upper surface of the substrate and a plurality of memory pillars penetrating the plurality of first wiring layers in the first direction;
a plurality of first bonding pads on the first chip;
a plurality of second bonding pads on the second chip and in contact with the plurality of first bonding pads;
a first electrode pad in a first plane parallel to the upper surface of the substrate with the plurality first bonding pads;
a second electrode pad facing the first electrode pad in the first direction and in a second plane parallel to the upper surface of the substrate with the plurality of second bonding pads, the second electrode pad being separated from the first electrode pad in the first direction; and
a first insulator layer interposed in the first direction between the first electrode pad and the second electrode pad.

2. The semiconductor memory device according to claim 1, further comprising:
a first dummy pad adjacent to the first electrode pad via a first insulator portion in the first plane; and
a second dummy pad adjacent to the second electrode pad via a second insulator portion in the second plane, wherein
the first dummy pad surrounds the first electrode pad in the first plane, and
the second dummy pad surrounds the second electrode pad in the second plane.

3. The semiconductor memory device according to claim 2, wherein
a first surface of the first dummy pad includes a portion on a side adjacent to the first electrode pad that is recessed in the first direction from a surface of the first chip,
a first surface of the second dummy pad includes a portion on a side adjacent to the second electrode pad that is recessed in the first direction from a surface of the second chip,
a first surface of the first electrode pad is recessed in the first direction from the surface of the first chip, and
a first surface of the second electrode pad is recessed in the first direction from the surface of the second chip.

4. The semiconductor memory device according to claim 3, wherein
a surface of the first insulator portion is recessed in the first direction from the surface of the first chip, and
a surface of the second insulator portion is recessed in the first direction from the surface of the second chip.

5. The semiconductor memory device according to claim 3, wherein
a second surface of the first dummy pad is located at approximately the same level as a second surface of the first electrode pad, and
a second surface of the second dummy pad is located at approximately the same level as a second surface of the second electrode pad.

6. The semiconductor memory device according to claim 1, further comprising:
a plurality of first dummy pads surrounding the first electrode pad via a first insulator portion in the first plane; and
a plurality of second dummy pads surrounding the second electrode pad via a second insulator portion in the second plane.

7. The semiconductor memory device according to claim 6, wherein
surfaces of the plurality of first dummy pads include portions on respective sides adjacent to the first electrode pad that are recessed in the first direction from a surface of the first chip,
surfaces of the plurality of second dummy pads include portions on respective sides adjacent to the second electrode pad that are recessed in the first direction from a surface of the second chip,
a surface of the first electrode pad is recessed in the first direction from the surface of the first chip, and
a surface of the second electrode pad is recessed in the first direction from the surface of the second chip.

8. The semiconductor memory device according to claim 6, wherein
a size of each of the plurality of first dummy pads in the first plane is the same as a size of the first electrode pad in the first plane, and
a size of each of the plurality of second dummy pads in the second plane is the same as a size of the second electrode pad in the second plane.

9. The semiconductor memory device according to claim 1, wherein a size of the first electrode pad in the first plane and a size of the second electrode pad in the second plane are different from each other.

10. The semiconductor memory device according to claim 1, wherein
the first chip further includes a circuit on the substrate, and
the first electrode pad and the second electrode pad are both electrically connected to the circuit.

11. The semiconductor memory device according to claim 10, wherein the second electrode pad is electrically connected to the circuit via one of the plurality of second bonding pads.

12. The semiconductor memory device according to claim 1, wherein
the first insulator layer is provided on just the first chip, and
the second electrode pad is in direct contact with the first insulator layer.

13. The semiconductor memory device according to claim 1, wherein
the first insulator layer is provided on just the second chip, and
the first electrode pad is in direct contact with the first insulator layer.

14. The semiconductor memory device according to claim 1, wherein
the first insulator layer comprises a first sub-insulator layer portion and a second sub-insulator layer portion that are arranged in the first direction,
the first sub-insulator layer portion is provided on just the first chip,
the second sub-insulator layer portion is provided on just the second chip, and
the first sub-insulator layer portion is in direct contact with the second sub-insulator layer portion.

15. The semiconductor memory device according to claim 14, wherein
a surface of the first sub-insulator layer portion is located at approximately the same level as a surface of the first chip, and
a surface of the second sub-insulator layer portion is located at approximately the same level as a surface of the second chip.

16. The semiconductor memory device according to claim 1, further comprising:
a third electrode pad in the first plane;
a fourth electrode pad facing the third electrode pad in the first direction and in the second plane, the fourth electrode pad being separated from the third electrode pad in the first direction; and
a second insulator layer interposed in the first direction between the third electrode pad and the fourth electrode pad.

17. The semiconductor memory device according to claim 1, wherein the first insulator layer comprises silicon oxide, silicon nitride, or nitrogen-doped silicon carbide.

18. The semiconductor memory device according to claim 1, wherein the plurality of first bonding pads, the plurality of second bonding pads, the first electrode pad, and the second electrode pad comprise copper.

19. The semiconductor memory device according to claim 1, wherein the first electrode pad, the second electrode pad, and the first insulator layer form a capacitor element.

20. The semiconductor memory device according to claim 1, wherein
a lower surface of the first electrode pad is located at approximately the same level as lower surfaces of the plurality of first bonding pads, and
an upper surface of the second electrode pad is located at approximately the same level as upper surfaces of the plurality of second bonding pads.
